(19) United States
(12) Patent Application Publication
(10) Pub. No.: US 2024/0107865 A1
(43) Pub. Date: Mar. 28, 2024

(54) MANUFACTURING EQUIPMENT FOR LIGHT-EMITTING DEVICE

(71) Applicant: SEMICONDUCTOR ENERGY LABORATORY CO., LTD., Atsugi-shi, Kanagawa-ken (JP)

(72) Inventors: Shingo EGUCHI, Atsugi, Kanagawa (JP); Hiroki ADACHI, Tochigi, Tochigi (JP); Kenichi OKAZAKI, Atsugi, Kanagawa (JP); Yasumasa YAMANE, Atsugi, Kanagawa (JP); Naoto KUSUMOTO, Isehara, Kanagawa (JP); Kensuke YOSHIZUMI, Atsugi, Kanagawa (JP); Shunpei YAMAZAKI, Setagaya, Tokyo (JP)

(21) Appl. No.: 18/275,431

(22) PCT Filed: Jan. 28, 2022
(86) PCT No.: PCT/IB2022/050738

§ 371 Date: Aug. 2, 2023

(30) Foreign Application Priority Data
Feb. 12, 2021 (JP) 2021-020546

(51) Int. Cl. H10K 71/16; C23C 14/04; C23C 14/56

(52) U.S. Cl. CPC H10K 71/166; C23C 14/042; C23C 14/566

(57) ABSTRACT

Manufacturing equipment for a light-emitting device with which steps from formation to sealing of a light-emitting element can be successively performed is provided. With the manufacturing equipment for a light-emitting device, a deposition step, a lithography step, and an etching step for forming an organic EL element and a sealing step by formation of a protective layer can be successively performed. Accordingly, a downscaled organic EL element with high luminance and high reliability can be formed. Moreover, the manufacturing equipment can have an in-line system where apparatuses are arranged in the order of process steps for the light-emitting device, resulting in high throughput manufacturing.

### TECHNICAL FIELD

One embodiment of the present invention relates to manufacturing equipment for a light-emitting device and a manufacturing method thereof.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Accordingly, more specific examples of the technical field of one embodiment of the present invention disclosed in this specification include a semiconductor device, a display device, a liquid crystal display device, a light-emitting apparatus, a lighting device, a power storage device, a memory device, an image capturing device, an operation method thereof, and a manufacturing method thereof.

### BACKGROUND ART

In recent years, higher-resolution display panels have been required. Examples of devices that require high-resolution display panels include a smartphone, a tablet terminal, and a notebook computer. Furthermore, higher resolution has been required for a stationary display device such as a television device or a monitor device along with an increase in definition. An example of a device required to have the highest resolution is a device for virtual reality (VR) or augmented reality (AR).

Examples of a display device that can be used for a display panel include, typically, a liquid crystal display device, a light-emitting apparatus including a light-emitting element such as an organic EL (Electro Luminescence) element or a light-emitting diode (LED), and electronic paper performing display by an electrophoretic method or the like.

An organic EL element has a structure where a layer containing a light-emitting organic compound is held between a pair of electrodes. By voltage application to this element, light emission can be obtained from the light-emitting organic compound. A display device using such an organic EL element does not need a backlight that is necessary for a liquid crystal display device and the like; thus, a thin, lightweight, high-contrast, and low-power display device can be achieved. Patent Document 1, for example, discloses an example of a display device using an organic EL element.

### REFERENCE

### Patent Document

[Patent Document 1] Japanese Published Patent Application No. 2002-324673

### SUMMARY OF THE INVENTION

### Problems to be Solved by the Invention

As an organic EL display device capable of full-color display, a structure in which white-light-emitting elements and color filters are combined and a structure in which R, G, and B light-emitting elements are formed in the same plane are known.

The latter structure is ideal in terms of power consumption, and light-emitting materials are separately deposited using a metal mask or the like in manufacture of medium- and small-sized panels under the existing circumstances. However, the process using a metal mask has low alignment accuracy and needs a reduction in the area occupied by light-emitting elements in a pixel, resulting in difficulty in increasing an aperture ratio.

Therefore, an issue of the process using a metal mask is to increase the density of pixels and emission intensity. It is preferable to increase the area of a light-emitting element with the use of a lithography step or the like for increasing the aperture ratio. However, the reliability of a material included in the light-emitting element is lowered when impurities (e.g., water, oxygen, and hydrogen) in the air enter the material, necessitating performing a plurality of steps in a controlled atmosphere.

In the case where a light-emitting element (also referred to as a light-emitting device) is fabricated with a vacuum evaporation method using a metal mask, an issue such as necessity of a plurality of manufacturing equipment lines arises. For example, since a metal mask has to be cleaned regularly, at least two or more manufacturing equipment lines are necessary, and one of the equipment lines is used for device fabrication while the other equipment line is being under maintenance. In consideration of mass production, a plurality of manufacturing equipment lines are required. Thus, the issue is that the initial investment for introducing manufacturing equipment significantly increases.

In view of this, an object of one embodiment of the present invention is to provide manufacturing equipment for a light-emitting device with which steps from formation to sealing of a light-emitting element can be successively performed without exposure to the air. Another object is to provide manufacturing equipment for a light-emitting device with which a light-emitting element can be formed without using a metal mask. Another object is to provide a method for manufacturing a light-emitting device.

Note that the description of these objects does not preclude the existence of other objects. One embodiment of the present invention does not have to achieve all the objects. Note that other objects will be apparent from the description of the specification, the drawings, the claims, and the like, and other objects can be derived from the description of the specification, the drawings, the claims, and the like.

### Means for Solving the Problems

One embodiment of the present invention relates to manufacturing equipment for a light-emitting device.

One embodiment of the present invention is manufacturing equipment for a light-emitting device, including first to eleventh clusters and first to tenth loadlock chambers. The first cluster is connected to the second cluster through the first loadlock chamber; the second cluster is connected to the third cluster through the second loadlock chamber; the third cluster is connected to the fourth cluster through the third loadlock chamber; the fourth cluster is connected to the fifth cluster through the fourth loadlock chamber; the fifth cluster is connected to the sixth cluster through the fifth loadlock chamber; the sixth cluster is connected to the seventh cluster through the sixth loadlock chamber; the seventh cluster is connected to the eighth cluster through the seventh loadlock chamber; the eighth cluster is connected to the ninth cluster through the eighth loadlock chamber; the ninth cluster is connected to the tenth cluster through the ninth loadlock chamber; the tenth cluster is connected to the eleventh cluster through the tenth loadlock chamber; pressures in the first cluster, the third cluster, the fourth cluster, the sixth cluster, the seventh cluster, the ninth cluster, and the eleventh cluster are controlled to reduced pressures; atmospheres in the second cluster, the fifth cluster, the eighth cluster, and the tenth cluster are controlled to inert gas atmospheres; the first cluster to the eleventh cluster each include a carrying device; the first cluster, the fourth cluster, the seventh cluster, and the eleventh cluster each include a face-up deposition apparatus and a face-down deposition apparatus; the third cluster, the sixth cluster, and the ninth cluster each include an etching apparatus; the second cluster, the fifth cluster, and the eighth cluster each include a plurality of apparatuses where a lithography step is performed; the tenth cluster includes an etching apparatus; and the face-down deposition apparatus includes a substrate reversing device.

Furthermore, a twelfth cluster and an eleventh loadlock chamber can be included. The twelfth cluster can be connected to the first cluster through the eleventh loadlock chamber, an atmosphere in the twelfth cluster can be controlled to an inert gas atmosphere, and the twelfth cluster can include a cleaning apparatus and a baking apparatus.

Furthermore, the twelfth cluster can include a load chamber, and the eleventh cluster can include an unload chamber.

Moreover, a thirteenth cluster, a fourteenth cluster, a twelfth loadlock chamber, and a thirteenth loadlock chamber may be included. The thirteenth cluster may be connected to the third cluster through the third loadlock chamber; the thirteenth cluster may be connected to the fourth cluster through the twelfth loadlock chamber; the fourteenth cluster may be connected to the sixth cluster through the sixth loadlock chamber; the fourteenth cluster may be connected to the seventh cluster through the thirteenth loadlock chamber; atmospheres in the thirteenth cluster and the fourteenth cluster may be controlled to inert gas atmospheres, and the thirteenth cluster and the fourteenth cluster may each include a cleaning apparatus and a baking apparatus.

The face-down deposition apparatus is preferably one or more selected from an evaporation apparatus and a sputtering apparatus.

The face-up deposition apparatus is preferably one or more selected from a CVD apparatus and an ALD apparatus.

The etching apparatus included in each of the third cluster, the sixth cluster, and the ninth cluster is preferably a dry etching apparatus.

The etching apparatus included in the tenth cluster is preferably a wet etching apparatus.

An application apparatus, a light-exposure apparatus, a developing apparatus, and a baking apparatus can be included as the plurality of apparatuses where the lithography step is performed. Alternatively, an application apparatus and a nanoimprint apparatus can be included as the plurality of apparatuses where the lithography step is performed.

The substrate reversing device can include a rotation mechanism and a stage where an electrostatic adsorption unit, an electromagnet unit, and a cylinder unit are stacked in this order. The electrostatic adsorption unit can hold a substrate. The rotation mechanism can reverse the stage.

The cylinder unit can have a function of moving up and down a plurality of pusher pins. The pusher pins can be provided in through holes formed in the electrostatic adsorption unit and the electromagnet unit.

The face-down deposition apparatus can include a mask jig and an alignment mechanism. The alignment mechanism can be connected to a lifting mechanism. After the stage is reversed, the mask jig can be aligned to touch the substrate and then can be closely attached to the substrate with the electromagnet unit.

### Effect of the Invention

According to one embodiment of the present invention, manufacturing equipment for a light-emitting device with which steps from formation to sealing of a light-emitting element can be successively performed without exposure to the air can be provided. Alternatively, manufacturing equipment for a light-emitting device with which a light-emitting element can be formed without using a metal mask can be provided. Further alternatively, a method for manufacturing a light-emitting device can be provided.

Note that the description of these effects does not preclude the existence of other effects. One embodiment of the present invention does not need to have all of these effects. Note that effects other than these can be derived from the description of the specification, the drawings, the claims, and the like.

### BRIEF DESCRIPTION OF THE DRAWINGS

FIG. 1 is a block diagram illustrating manufacturing equipment.

FIG. 2 is a diagram illustrating manufacturing equipment.

FIG. 3 is a diagram illustrating manufacturing equipment.

FIG. 4 is a diagram illustrating manufacturing equipment.

FIG. 5 is a diagram illustrating manufacturing equipment.

FIG. 6 is a block diagram illustrating manufacturing equipment.

FIG. 7 is a diagram illustrating manufacturing equipment.

FIG. 8 is a diagram illustrating manufacturing equipment.

FIG. 9 is a block diagram illustrating manufacturing equipment.

FIG. 10 is a diagram illustrating manufacturing equipment.

FIG. 11 is a diagram illustrating manufacturing equipment.

FIG. 12A to FIG. 12C are diagrams illustrating a deposition apparatus.

FIG. 13A to FIG. 13C are diagrams illustrating carrying a substrate to a deposition apparatus and operation of the deposition apparatus.

FIG. 14A and FIG. 14B are diagrams illustrating operation of a deposition apparatus. FIG. 14C is a diagram illustrating a mask unit.

FIG. 15 is a diagram illustrating a display device.

FIG. 16A to FIG. 16C are diagrams each illustrating a display device.

FIG. 17A to FIG. 17D are diagrams illustrating a manufacturing method of a display device.

FIG. 18A to FIG. 18D are diagrams illustrating a manufacturing method of a display device.

FIG. 19A to FIG. 19E are diagrams illustrating a manufacturing method of a display device.

FIG. 20 is a diagram illustrating manufacturing equipment.

### MODE FOR CARRYING OUT THE INVENTION

Embodiments are described in detail with reference to the drawings. Note that the present invention is not limited to the following description, and it will be readily understood by those skilled in the art that modes and details of the present invention can be modified in various ways without departing from the spirit and scope of the present invention. Therefore, the present invention should not be construed as being limited to the description of embodiments below. Note that in structures of the invention described below, the same reference numerals are used in common, in different drawings, for the same portions or portions having similar functions, and a repeated description thereof is omitted in some cases. Note that the hatching of the same component that constitutes a drawing is sometimes omitted or changed as appropriate in different drawings.

### Embodiment 1

In this embodiment, manufacturing equipment for a light-emitting device that is one embodiment of the present invention is described with reference to drawings.

One embodiment of the present invention is manufacturing equipment mainly used for formation of a display device including a light-emitting device such as an organic EL element. It is preferable to use a lithography step in order to downscale the organic EL element or increase the area occupied by the organic EL element in a pixel. However, the reliability is impaired when impurities such as water, oxygen, and hydrogen enter the organic EL element. Therefore, it is necessary to take measures so that a surface and side surfaces of a patterned organic layer are not exposed to the air, and that the atmosphere is controlled to have a low dew point from the manufacturing stage, for example.

With the manufacturing equipment of one embodiment of the present invention, a deposition step, a lithography step, an etching step, and a sealing step for forming an organic EL element can be successively performed without exposure to the air. Accordingly, a downscaled organic EL element with high luminance and high reliability can be formed. Moreover, the manufacturing equipment of one embodiment of the present invention can have an in-line system where apparatuses are arranged in the order of process steps for the light-emitting device, resulting in high throughput manufacturing.

As a support substrate for forming an organic EL element, a large-sized substrate such as a glass substrate can be used. A glass substrate where a pixel circuit and the like are formed in advance is used as a support substrate, and an organic EL element can be formed over these circuits. As the glass substrate, for example, a large-sized rectangular substrate with a size of G5 to G10 can be used. Note that the glass substrate is not limited thereto and a round substrate, a small-sized substrate, and the like can also be used.

### Structure Example 1

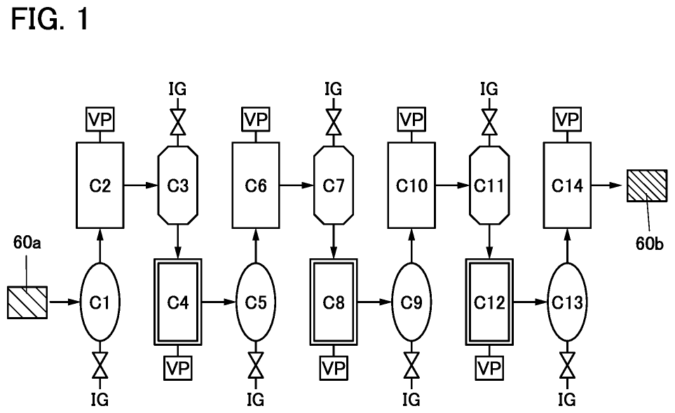

FIG. 1 is a block diagram illustrating the manufacturing equipment for a light-emitting device that is one embodiment of the present invention. The manufacturing equipment includes a plurality of clusters arranged in the order of process steps. In this specification, a group of apparatuses which shares a carrying device or the like is called a cluster. A substrate where light-emitting devices are formed is moved between the clusters in sequence, so that the steps are conducted.

The manufacturing equipment illustrated in FIG. 1 is an example including a cluster C1 to a cluster C14. The cluster C1 to the cluster C14 are connected in sequence. A substrate 60a brought into the cluster C1 can be taken out from the cluster C14 as a substrate 60b where a light-emitting device is formed.

The clusters C1, C3, C5, C7, C9, C11, and C13 each include a group of apparatuses for performing a process under atmosphere control. The clusters C2, C4, C6, C8, C10, C12, and C14 each include a group of apparatuses for performing vacuum processing (process under reduced pressure).

The clusters C1, C5, and C9 include apparatuses mainly for cleaning and baking the substrate, and the like. The clusters C2, C6, and C10 each include apparatuses mainly for forming an organic compound included in the light-emitting device and the like. The clusters C3, C7, and C11 each include apparatuses mainly for performing a lithography step, and the like. The clusters C4, C8, and C12 each include apparatuses mainly for performing an etching step and an ashing step, and the like. The cluster C13 includes apparatuses for an etching step and cleaning the substrate, and the like. The cluster C14 includes apparatuses mainly for forming an organic compound included in the light-emitting device and forming a protective film to seal the light-emitting device, and the like.

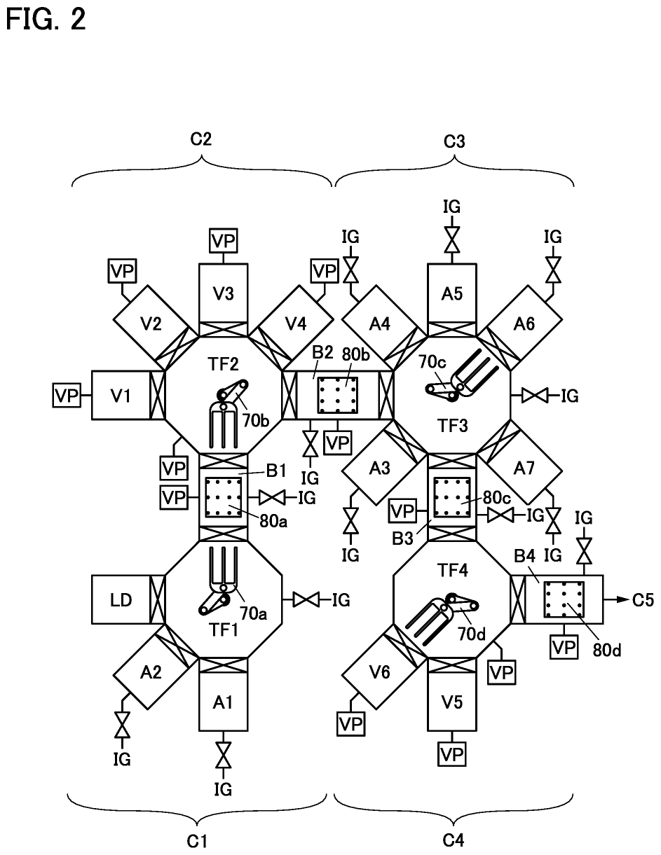

Next, the cluster C1 to the cluster C14 are described in detail with reference to FIGS. 2 to FIG. 5.

### <Cluster C1 to Cluster C4>

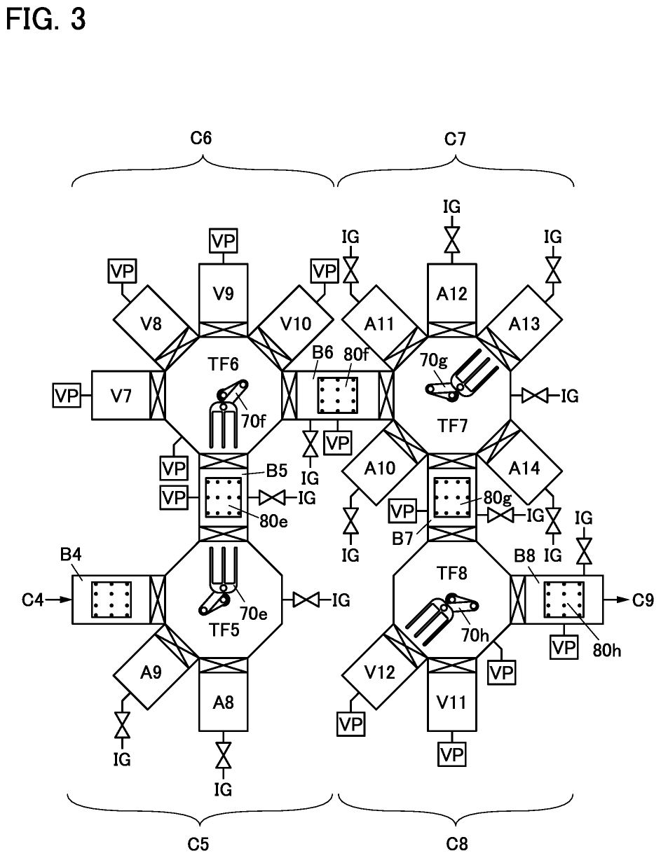

FIG. 2 is a top view illustrating the cluster C1 to the cluster C4. The cluster C1 is connected to the cluster C2 through a loadlock chamber B1. The cluster C2 is connected to the cluster C3 through a loadlock chamber B2. The cluster C3 is connected to the cluster C4 through a loadlock chamber B3. The cluster C4 is connected to the cluster C5 (see FIG. 3) through a loadlock chamber B4.

### <Normal-Pressure Process Apparatus A>

The cluster C1 and the cluster C3 each include normal-pressure process apparatuses A. The cluster C1 includes a transfer chamber TF1 and the normal-pressure process apparatuses A (normal-pressure process apparatuses A1 and A2) where processing is performed mainly under a normal pressure. The cluster C3 includes a transfer chamber TF3 and the normal-pressure process apparatuses A (normal-pressure process apparatuses A3 to A7). In the cluster C1, a load chamber LD is provided.

Note that the number of the normal-pressure process apparatuses A included in each of the clusters may be one or more depending on the purpose. Note that the normal-pressure process apparatus A is not necessarily used for steps under a normal pressure, and the pressure of the normal-pressure process apparatus A may be controlled to a negative pressure or a positive pressure that shifts slightly from the normal pressure. In the case where a plurality of normal-pressure process apparatuses A are provided, the pressures therein may be different from each other.

Valves for introducing an inert gas (IG) are connected to the transfer chambers TF1 and TF3 and the normal-pressure process apparatuses A, whereby the atmosphere therein can be controlled to an inert gas atmosphere. Examples of the inert gas that can be used include nitrogen and a noble gas such as argon or helium. In addition, the inert gas preferably has a low dew point (e.g., −50° C. or lower). When a step is performed under an atmosphere of an inert gas with a low dew point, entry of impurities can be prevented and a highly reliable organic EL element can be formed.

As the normal-pressure process apparatuses A included in the cluster C1, a cleaning apparatus, a baking apparatus, and the like can be employed. For example, a spin cleaning apparatus, a hot plate-type baking apparatus, and the like can be employed. The baking apparatus may be a vacuum baking apparatus.

As the normal-pressure process apparatuses A included in the cluster C3, apparatuses for performing a lithography step can be used. For example, in the case where a photolithography step is performed, a resin (photoresist) application apparatus, a light-exposure apparatus, a development apparatus, a baking apparatus, and the like can be employed. In the case where a nanoimprint lithography step is performed, a resin (e.g., a UV curable resin) application apparatus, a nanoimprint apparatus, and the like can be employed. In addition, depending on the usage, a cleaning apparatus, a wet etching apparatus, an application apparatus, a resist peeling apparatus, and the like may be employed as the normal-pressure process apparatuses A.

In the example of the cluster C1, the normal-pressure process apparatuses A1 and A2 are each connected to the transfer chamber TF1 through a gate valve. In the example of the cluster C3, the normal-pressure process apparatuses A3 to A7 are each connected to the transfer chamber TF3 through a gate valve. Providing the gate valve makes it possible to control pressure, control the kind of an inert gas, and prevent cross contamination, for example.

The transfer chamber TF1 is connected to the load chamber LD through a gate valve. The transfer chamber TF1 is also connected to the loadlock chamber B1 through another gate valve. The transfer chamber TF1 is provided with a carrying device 70a. The carrying device 70a can carry the substrate into the normal-pressure process apparatus A from the load chamber LD. In addition, the carrying device 70a can carry out the substrate taken from the normal-pressure process apparatus A into the loadlock chamber B1.

The transfer chamber TF3 is connected to the loadlock chamber B2 through a gate valve. The transfer chamber TF3 is also connected to the loadlock chamber B3 through another gate valve. The transfer chamber TF3 is provided with a carrying device 70c. The carrying device 70c can carry the substrate into the normal-pressure process apparatus A from the loadlock chamber B2. In addition, the carrying device 70c can carry out the substrate taken from the normal-pressure process apparatus A into the loadlock chamber B3.

### <Vacuum Process Apparatus V>

The cluster C2 and the cluster C4 each include vacuum process apparatuses V. The cluster C2 includes a transfer chamber TF2 and the vacuum process apparatuses V (vacuum process apparatuses V1 to V4). The cluster C4 includes a transfer chamber TF4 and the vacuum process apparatuses V (vacuum process apparatuses V5 and V6).

Note that the number of the vacuum process apparatuses V included in each of the clusters may be one or more depending on the purpose. A vacuum pump VP is connected to each vacuum process apparatus V, and a gate valve is provided between each vacuum process apparatus V and the transfer chamber TF (transfer chambers TF2 and TF4). Thus, different processes can be performed in parallel in the vacuum process apparatuses V.

Note that the vacuum process means treatment in an environment where the pressure is controlled to a reduced pressure. Thus, the vacuum process includes treatment for performing pressure control under a reduced pressure with introduction of a process gas, besides treatment under high vacuum.

The transfer chambers TF2 and TF4 are also provided with an independent vacuum pump VP, so that cross contamination during processes performed in the vacuum process apparatuses V can be prevented.

As the vacuum process apparatuses V included in the cluster C2, deposition apparatuses such as an evaporation apparatus, a sputtering apparatus, a CVD (Chemical Vapor Deposition) apparatus, and an ALD (Atomic Layer Deposition) apparatus can be employed, for example. As the CVD apparatus, a thermal CVD apparatus using heat, a PECVD apparatus (Plasma Enhanced CVD apparatus) using plasma, or the like can be used. As the ALD apparatus, a thermal ALD apparatus using heat, a PEALD apparatus (Plasma Enhanced ALD apparatus) using a plasma-excited reactant, or the like can be used.

As the vacuum process apparatuses V included in the cluster C4, a dry etching apparatus, an ashing apparatus, or the like can be employed, for example.

Note that in this embodiment, an apparatus in which a substrate is placed with a deposition surface facing downward is referred to as a face-down apparatus. In contrast, an apparatus in which a substrate is placed with a deposition surface facing upward is referred to as a face-up apparatus. Examples of the face-down apparatus include a deposition apparatus such as an evaporation apparatus or a sputtering apparatus. Examples of the face-up apparatus include a deposition apparatus such as a CVD apparatus or an ALD apparatus, a dry etching apparatus, an ashing apparatus, a baking apparatus, and an apparatus involving lithography. Note that the manufacturing equipment in this embodiment includes any of apparatuses other than the above in some cases. For example, a face-up sputtering apparatus can also be used.

The transfer chamber TF2 is connected to the loadlock chamber B1 through a gate valve. The transfer chamber TF2 is also connected to the loadlock chamber B2 through another gate valve. The transfer chamber TF2 is provided with a carrying device 70b. The carrying device 70b can carry the substrate placed in the loadlock chamber B1 to the vacuum process apparatus V. In addition, the carrying device 70b can carry out the substrate taken from the vacuum process apparatus V into the loadlock chamber B2.

The transfer chamber TF4 is connected to the loadlock chamber B3 through a gate valve. The transfer chamber TF4 is also connected to the loadlock chamber B4 through another gate valve. The transfer chamber TF4 is provided with a carrying device 70d. With the carrying device 70d, the substrate can be carried from the loadlock chamber B3 into the vacuum process apparatus V and carried out to the loadlock chamber B4.

The loadlock chambers B1, B2, B3, and B4 are each provided with a valve for introducing an inert gas and the vacuum pump VP. Thus, the loadlock chambers B1, B2, B3, and B4 can be controlled so as to be under a reduced pressure or an inert gas atmosphere. For example, in the case where the substrate is carried from the cluster C2 to the cluster C3, it is possible that the substrate is carried from the cluster C2 into the loadlock chamber B2 under a reduced pressure, and the substrate is carried out to the cluster C3 after the atmosphere in the loadlock chamber B2 is changed to an inert gas atmosphere.

Note that the carrying devices 70a, 70b, 70c, and 70d each have a mechanism for carrying the substrate placed on a hand portion. The hand portion may be provided with a vacuum adsorption mechanism or the like because the carrying devices 70a and 70c work under a normal pressure. The hand portion may be provided with an electrostatic adsorption mechanism or the like because the carrying devices 70b and 70d work under a reduced pressure.

Stages 80a, 80b, 80c, and 80d where a substrate can be placed on pins are provided in the loadlock chambers B1, B2, B3, and B4, respectively. Note that these stages are just examples and a stage with another structure may be employed.

### <Cluster C5 to Cluster C8>

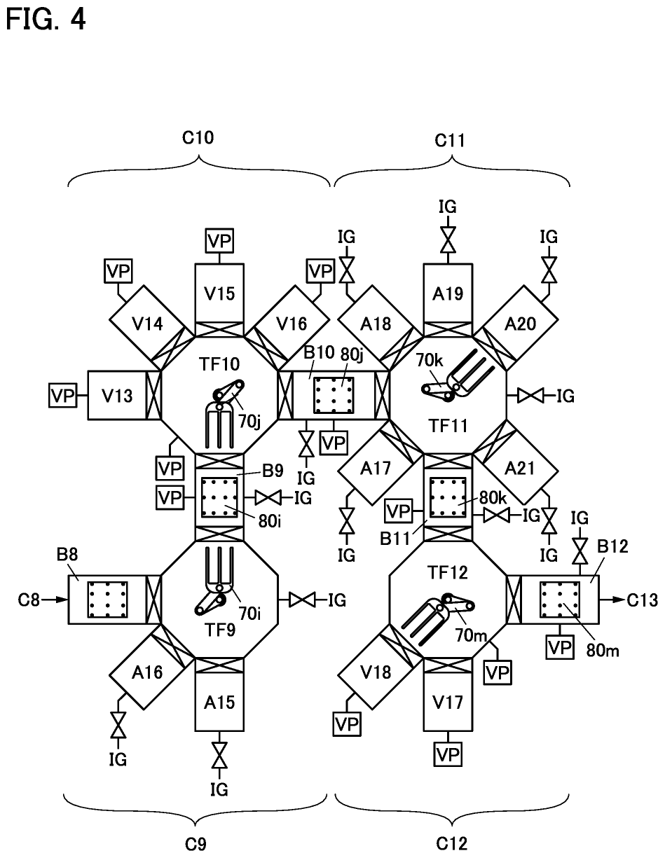

FIG. 3 is a top view illustrating the cluster C5 to the cluster C8. The cluster C5 is connected to the cluster C6 through a loadlock chamber B5. The cluster C6 is connected to the cluster C7 through a loadlock chamber B6. The cluster C7 is connected to the cluster C8 through a loadlock chamber B7. The cluster C8 is connected to the cluster C9 (see FIG. 4) through the loadlock chamber B8.

The basic structures of the cluster C5 to the cluster C8 are similar to those of the cluster C1 to the cluster C4. The cluster C5 corresponds to the cluster C1, the cluster C6 corresponds to the cluster C2, the cluster C7 corresponds to the cluster C3, and the cluster C8 corresponds to the cluster C4. Note that the load chamber LD in the cluster C1 is replaced with the loadlock chamber B4 in the cluster C5.

In addition, the loadlock chamber B5 corresponds to the loadlock chamber B1, the loadlock chamber B6 corresponds to the loadlock chamber B2, the loadlock chamber B7 corresponds to the loadlock chamber B3, and the loadlock chamber B8 corresponds to the loadlock chamber B4.

Structures only will be described below. For details of the clusters and the loadlock chambers, description of the cluster C1 to the cluster C4 and the loadlock chambers B1 to B4 can be referred to.

The cluster C5 and the cluster C7 each include normal-pressure process apparatuses A. The cluster C5 includes a transfer chamber TF5 and the normal-pressure process apparatuses A (normal-pressure process apparatuses A8 and A9) where processing is performed mainly under a normal pressure. The cluster C7 includes a transfer chamber TF7 and the normal-pressure process apparatuses A (normal-pressure process apparatuses A10 to A14).

The transfer chamber TF5 is connected to the loadlock chamber B4 through a gate valve. The transfer chamber TF5 is also connected to the loadlock chamber B5 through another gate valve. The transfer chamber TF5 is provided with a carrying device 70e. The carrying device 70e can carry the substrate into the normal-pressure process apparatus A from the loadlock chamber B4. In addition, the carrying device 70e can carry out the substrate taken from the normal-pressure process apparatus A into the loadlock chamber B5.

The transfer chamber TF7 is connected to the loadlock chamber B6 through a gate valve. The transfer chamber TF7 is also connected to the loadlock chamber B7 through another gate valve. The transfer chamber TF7 is provided with a carrying device 70g. The carrying device 70g can carry the substrate into the normal-pressure process apparatus A from the loadlock chamber B6. In addition, the carrying device 70g can carry out the substrate taken from the normal-pressure process apparatus A into the loadlock chamber B7.

The cluster C6 and the cluster C8 each include the vacuum process apparatuses V. The cluster C6 includes a transfer chamber TF6 and the vacuum process apparatuses V (vacuum process apparatuses V7 to V10). The cluster C8 includes a transfer chamber TF8 and the vacuum process apparatuses V (vacuum process apparatuses V11 and V12).

The transfer chamber TF6 is connected to the loadlock chamber B5 through a gate valve. The transfer chamber TF6 is also connected to the loadlock chamber B6 through another gate valve. The transfer chamber TF6 is provided with a carrying device 70f The carrying device 70f can carry the substrate placed in the loadlock chamber B5 into the vacuum process apparatus V. The carrying device 70f can carry out the substrate taken from the vacuum process apparatus V into the loadlock chamber B6.

The transfer chamber TF8 is connected to the loadlock chamber B7 through a gate valve. The transfer chamber TF8 is also connected to the loadlock chamber B8 through another gate valve. The transfer chamber TF8 is provided with a carrying device 70h. The carrying device 70h can carry the substrate from the loadlock chamber B7 into the vacuum process apparatus V. The carrying device 70h can carry out the substrate taken from the vacuum process apparatus V into the loadlock chamber B8.

Stages 80e, 80f, 80g, and 80h where a substrate can be placed on pins are provided in the loadlock chambers B5, B6, B7, and B8, respectively.

### <Cluster C9 to Cluster C12>

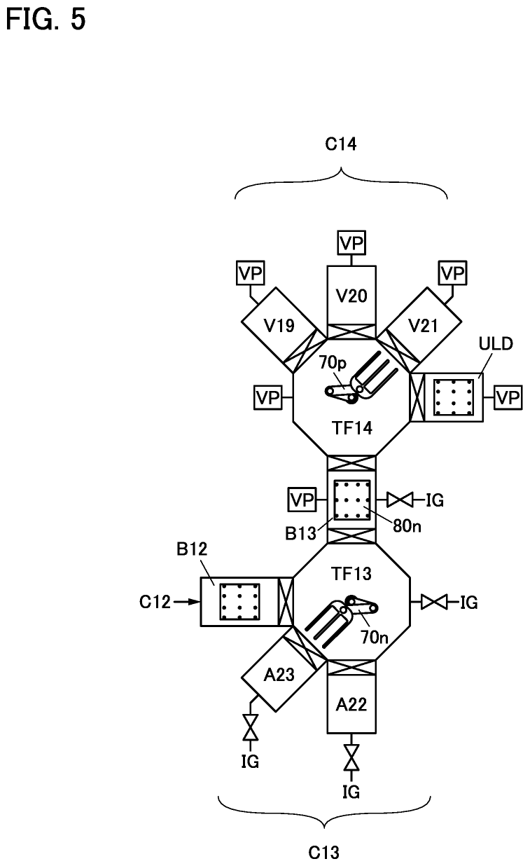

FIG. 4 is a top view illustrating the cluster C9 to the cluster C12. The cluster C9 is connected to the cluster C10 through a loadlock chamber B9. The cluster C10 is connected to the cluster C11 through a loadlock chamber B10. The cluster C11 is connected to the cluster C12 through a loadlock chamber B11. The cluster C12 is connected to the cluster C13 (see FIG. 5) through a loadlock chamber B12.

The basic structures of the cluster C9 to the cluster C12 are similar to those of the cluster C1 to the cluster C4. The cluster C9 corresponds to the cluster C1, the cluster C10 corresponds to the cluster C2, the cluster C11 corresponds to the cluster C3, and the cluster C12 corresponds to the cluster C4. Note that the load chamber LD in the cluster C1 is replaced with the loadlock chamber B8 in the cluster C5.

In addition, the loadlock chamber B9 corresponds to the loadlock chamber B1, the loadlock chamber B10 corresponds to the loadlock chamber B2, the loadlock chamber B11 corresponds to the loadlock chamber B3, and the loadlock chamber B12 corresponds to the loadlock chamber B4.

Structures only will be described below. For details of the clusters and the loadlock chambers, description of the cluster C1 to the cluster C4 and the loadlock chambers B1 to B4 can be referred to.

The cluster C9 and the cluster C11 each include the normal-pressure process apparatuses A. The cluster C9 includes a transfer chamber TF9 and the normal-pressure process apparatuses A (normal-pressure process apparatuses A15 and A16) where processing is performed mainly under a normal pressure. The cluster C11 includes a transfer chamber TF11 and the normal-pressure process apparatuses A (normal-pressure process apparatuses A17 to A21).

The transfer chamber TF9 is connected to the loadlock chamber B8 through a gate valve. The transfer chamber TF9 is also connected to the loadlock chamber B9 through another gate valve. The transfer chamber TF9 is provided with a carrying device 70i. The carrying device 70i can carry the substrate into the normal-pressure process apparatus A from the loadlock chamber B8. In addition, the carrying device 70i can carry out the substrate taken from the normal-pressure process apparatus A into the loadlock chamber B9.

The transfer chamber TF11 is connected to the loadlock chamber B10 through a gate valve. The transfer chamber TF11 is also connected to the loadlock chamber B11 through another gate valve. The transfer chamber TF11 is provided with a carrying device 70k. The carrying device 70k can carry the substrate into the normal-pressure process apparatus A from the loadlock chamber B10. In addition, the carrying device 70k can carry out the substrate taken from the normal-pressure process apparatus A into the loadlock chamber B11.

The cluster C10 and the cluster C12 each include the vacuum process apparatuses V. The cluster C10 includes a transfer chamber TF10 and the vacuum process apparatuses V (vacuum process apparatuses V13 to V16). The cluster C12 includes a transfer chamber TF12 and the vacuum process apparatuses V (vacuum process apparatuses V17 and V18).

The transfer chamber TF10 is connected to the loadlock chamber B9 through a gate valve. The transfer chamber TF10 is also connected to the loadlock chamber B10 through another gate valve. The transfer chamber TF10 is provided with a carrying device 70j. The carrying device 70j can carry the substrate placed in the loadlock chamber B9 into the vacuum process apparatus V. The carrying device 70j can carry out the substrate taken from the vacuum process apparatus V into the loadlock chamber B10.

The transfer chamber TF12 is connected to the loadlock chamber B11 through a gate valve. The transfer chamber TF12 is also connected to the loadlock chamber B12 through another gate valve. The transfer chamber TF12 is provided with a carrying device 70m. With the carrying device 70m, the substrate can be carried from the loadlock chamber B11 into the vacuum process apparatus V and carried out to the loadlock chamber B12.

Stages 80i, 80j, 80k, and 80m where a substrate can be placed on pins are provided in the loadlock chambers B9, B10, B11, and B12, respectively.

### <Clusters C13 and C14>

FIG. 5 is a top view illustrating the clusters C13 and C14. The cluster C13 is connected to the cluster C14 through a loadlock chamber B13. Note that the description of portions that are in common with those in the clusters C1, C2, and the like is omitted.

The cluster C13 includes the normal-pressure process apparatuses A. The cluster C13 includes a transfer chamber TF13 and the normal-pressure process apparatuses A (normal-pressure process apparatuses A22 and A23) where processing is performed mainly under a normal pressure.

As the normal-pressure process apparatuses A included in the cluster C13, an etching apparatus, a baking apparatus, and the like can be employed. For example, a wet etching apparatus, a hot plate-type baking apparatus, and the like can be employed. The baking apparatus may be a vacuum baking apparatus.

The transfer chamber TF13 is connected to the loadlock chamber B12 through a gate valve. The transfer chamber TF13 is also connected to the loadlock chamber B13 through another gate valve. The transfer chamber TF13 is provided with a carrying device 70n. The carrying device 70n can carry the substrate into the normal-pressure process apparatus A from the loadlock chamber B12. In addition, the carrying device 70n can carry out the substrate taken from the normal-pressure process apparatus A into the loadlock chamber B13.

As the vacuum apparatuses V included in the cluster C14, for example, deposition apparatuses such as an evaporation apparatus, a sputtering apparatus, a CVD apparatus, and an ALD apparatus, an apparatus for attaching a counter substrate to a substrate, or the like can be employed.

The loadlock chamber B13 is provided with a valve for introducing an inert gas and the vacuum pump VP. Thus, the loadlock chamber B13 can be controlled so as to be under a reduced pressure or an inert gas atmosphere. In addition, the loadlock chamber B13 is provided with a stage 80n where a substrate can be placed on pins.

The transfer chamber TF14 is connected to the loadlock chamber B13 through a gate valve. The transfer chamber TF14 is also connected to an unload chamber ULD through another gate valve. The transfer chamber TF14 is provided with a carrying device 70p. The carrying device 70p can carry the substrate from the loadlock chamber B13 into the vacuum process apparatus V. In addition, the carrying device 70p can carry out the substrate taken from the vacuum process apparatus V into the unload chamber ULD.

With use of the manufacturing equipment having the above structure, highly reliable light-emitting device sealed with a protective film can be formed.

For example, the following steps can be performed successively in the equipment under a controlled atmosphere: a step of forming an organic EL element emitting light of a first color in the clusters C1 to C4; a step of forming an organic EL element emitting light of a second color in the clusters C5 to C8; a step of forming an organic EL element emitting light of a third color in the clusters C9 to C12; a step of removing an unnecessary element in the cluster C13, and a step of forming a protective film in the cluster C14. Details of these steps are described later.

### Structural Example 2

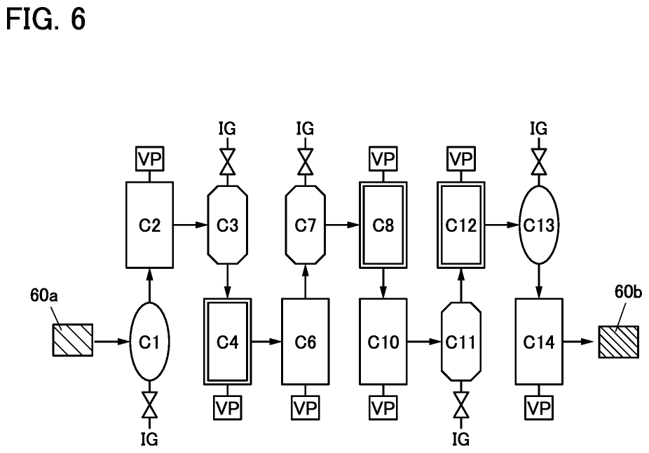

FIG. 6 is a block diagram illustrating manufacturing equipment for a light-emitting device different from that in FIG. 1. The manufacturing equipment illustrated in FIG. 6 is an example in which the clusters C1, C2, C3, C4, C6, C7, C8, C10, C11, C12, C13, and C14 are included, which is a structure excluding the clusters C5 and C9 from the manufacturing equipment illustrated in FIG. 1. The clusters C1, C2, C3, C4, C6, C7, C8, C10, C11, C12, C13, and C14 are connected in sequence and the substrate 60a brought into the cluster C1 can be taken out from the cluster C14 as the substrate 60b where a light-emitting device is formed.

In the manufacturing equipment illustrated in FIG. 1, the clusters C5 and C9 include a cleaning apparatus and a baking apparatus. The steps prior to the cleaning step are an etching (dry etching) and an ashing step. If residual gas components, residues, deposited matters, and the like in these steps do not adversely affect succeeding steps, the cleaning step can be omitted. In the case where the cleaning step is omitted, it is unnecessary to consider residual water or the like in a substrate, and thus the baking step can also be unnecessary. Accordingly, the structure of FIG. 6, which is obtained by excluding the clusters C5 and C9 from the manufacturing equipment illustrated in FIG. 1, can be employed depending on cases. The total number of the clusters and the loadlock chambers can be reduced by excluding the clusters C5 and C9.

### <Cluster C1 to Cluster C4>

The structures of the cluster C1 to cluster C4 can be similar to those illustrated in FIG. 2. Note that the loadlock chamber B4 is connected to the cluster C6.

### <Clusters C6, C7, C8, and C10>

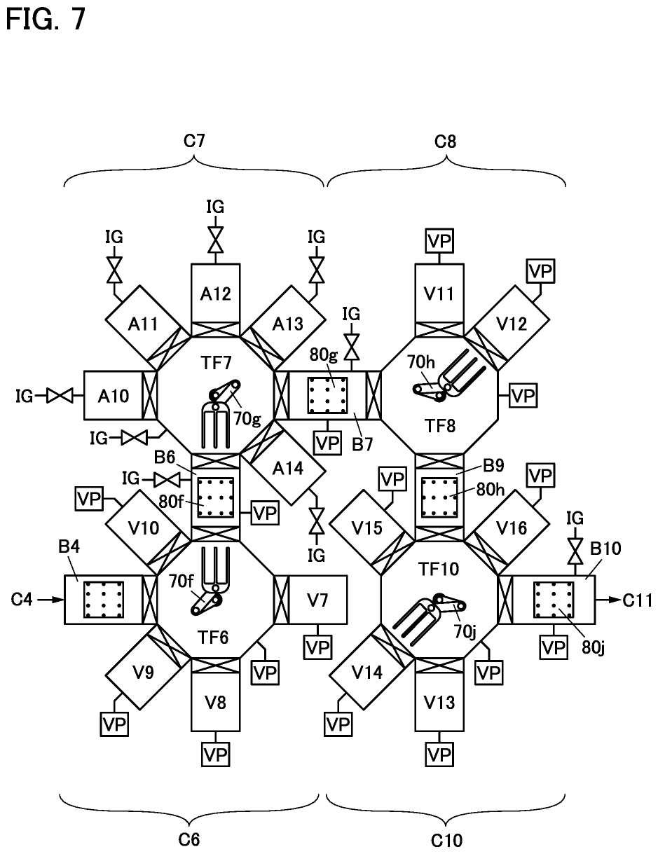

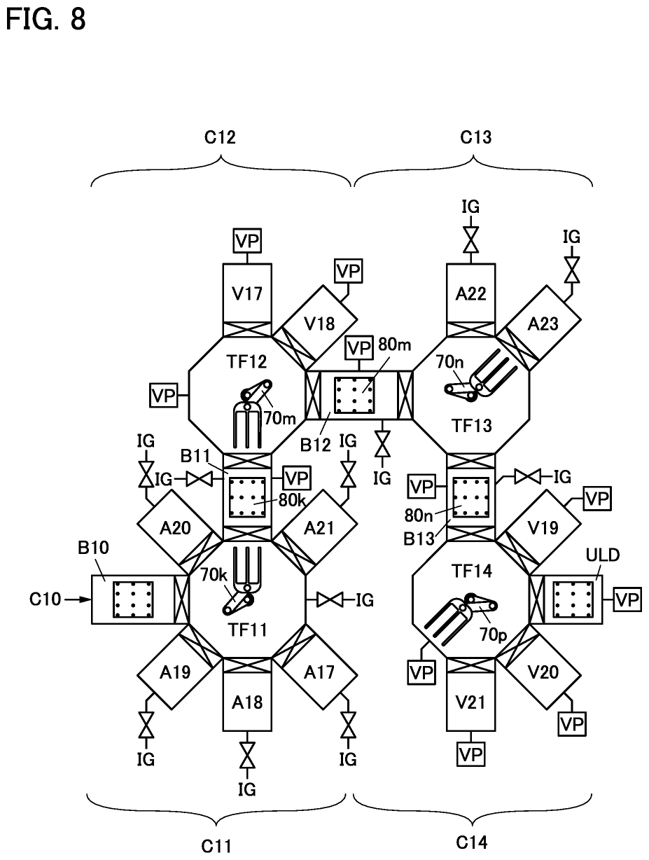

FIG. 7 is a top view illustrating the clusters C6, C7, C8, and C10. The cluster C6 is connected to the cluster C7 through the loadlock chamber B6. The cluster C7 is connected to the cluster C8 through the loadlock chamber B7. The cluster C8 is connected to the cluster C10 through the loadlock chamber B9. The cluster C10 is connected to the cluster C11 (see FIG. 8) through the loadlock chamber B10.

The connections between the clusters are described below. For the details of the clusters and the loadlock chambers, the description of the clusters C6, C7, C8, and C10 and the loadlock chambers B4, B7, B9, and B10 can be referred to.

The transfer chamber TF6 included in the cluster C6 is connected to the loadlock chamber B4 through a gate valve. The transfer chamber TF6 is also connected to the loadlock chamber B6 through another gate valve. The transfer chamber TF6 is provided with the carrying device 70f The carrying device 70f can carry the substrate placed in the loadlock chamber B4 into the vacuum process apparatus V. The carrying device 70f can carry out the substrate taken from the vacuum process apparatus V into the loadlock chamber B6.

The transfer chamber TF7 included in the cluster C7 is connected to the loadlock chamber B6 through a gate valve. The transfer chamber TF7 is also connected to the loadlock chamber B7 through another gate valve. The transfer chamber TF7 is provided with the carrying device 70g. The carrying device 70g can carry the substrate into the normal-pressure process apparatus A from the loadlock chamber B6. In addition, the carrying device 70g can carry out the substrate taken from the normal-pressure process apparatus A into the loadlock chamber B7.

The transfer chamber TF8 included in the cluster C8 is connected to the loadlock chamber B7 through a gate valve. The transfer chamber TF8 is also connected to the loadlock chamber B9 through another gate valve. The transfer chamber TF8 is provided with the carrying device 70h. The carrying device 70h can carry the substrate from the loadlock chamber B7 into the vacuum process apparatus V. The carrying device 70h can carry out the substrate taken from the vacuum process apparatus V into the loadlock chamber B9.

The transfer chamber TF10 included in the cluster C10 is connected to the loadlock chamber B9 through a gate valve. The transfer chamber TF10 is also connected to the loadlock chamber B10 through another gate valve. The transfer chamber TF10 is provided with the carrying device 70j. The carrying device 70j can carry the substrate placed in the loadlock chamber B9 into the vacuum process apparatus V. The carrying device 70j can carry out the substrate taken from the vacuum process apparatus V into the loadlock chamber B10.

### <Clusters C11, C12, C13, and C14>

FIG. 8 is a top view illustrating the clusters C11, C12, C13, and C14. The cluster C11 is connected to the cluster C12 through the loadlock chamber B11. The cluster C12 is connected to the cluster C13 through the loadlock chamber B12. The cluster C13 is connected to the cluster C14 through the loadlock chamber B13.

The connections between the clusters are described below. For the details of the clusters and the loadlock chambers, the description of the clusters C11, C12, C13, and C14 and the loadlock chambers B11, B12, and B13 can be referred to.

The transfer chamber TF11 included in the cluster C11 is connected to the loadlock chamber B10 through a gate valve. The transfer chamber TF11 is also connected to the loadlock chamber B11 through another gate valve. The transfer chamber TF11 is provided with the carrying device 70k. The carrying device 70k can carry the substrate into the normal-pressure process apparatus A from the loadlock chamber B10. In addition, the carrying device 70k can carry out the substrate taken from the normal-pressure process apparatus A into the loadlock chamber B11.

The transfer chamber TF12 included in the cluster C12 is connected to the loadlock chamber B11 through a gate valve. The transfer chamber TF12 is also connected to the loadlock chamber B12 through another gate valve. The transfer chamber TF12 is provided with the carrying device 70m. The carrying device 70m can carry the substrate from the loadlock chamber B11 into the vacuum process apparatus V. In addition, the carrying device 70m can carry out the substrate taken from the vacuum process apparatus V into the loadlock chamber B12.

The transfer chamber TF13 included in the cluster C13 is connected to the loadlock chamber B12 through a gate valve. The transfer chamber TF13 is also connected to the loadlock chamber B13 through another gate valve. The transfer chamber TF13 is provided with the carrying device 70n. The carrying device 70n can carry the substrate into the normal-pressure process apparatus A from the loadlock chamber B12. In addition, the carrying device 70n can carry out the substrate taken from the normal-pressure process apparatus A into the loadlock chamber B13.

The transfer chamber TF14 included in the cluster C14 is connected to the loadlock chamber B13 through a gate valve. The transfer chamber TF14 is also connected to the unload chamber ULD through another gate valve. The transfer chamber TF14 is provided with the carrying device 70p. The carrying device 70p can carry the substrate from the loadlock chamber B13 into the vacuum process apparatus V. In addition, the carrying device 70p can carry out the substrate taken from the vacuum process apparatus V into the unload chamber ULD.

### Structure Example 3

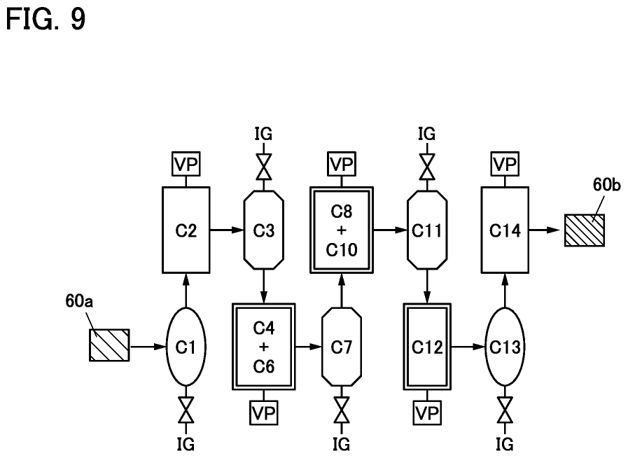

FIG. 9 is a block diagram illustrating a variation example of the manufacturing equipment for the light-emitting device illustrated in FIG. 6. In the manufacturing equipment illustrated in FIG. 9, the cluster C4 and the cluster C6 are combined to one cluster and the cluster C8 and the cluster C10 are combined to one cluster. Note that the combined clusters are referred to as the cluster C4+C6 and the cluster C8+C10.

In the manufacturing equipment illustrated in FIG. 6, the cluster C4 is connected to the cluster C6 through the loadlock chamber B4. That is, the substrate is carried into the cluster C6 from the cluster C4 and steps are performed.

Here, the cluster C4 and cluster C6 are each a cluster including the vacuum process apparatus V. There is an upper limit on the number of vacuum process apparatuses that can be connected to the transfer chamber; however, if the number of vacuum process apparatuses V included in each of the cluster C4 and the cluster C6 does not exceed the upper limit, the both can be combined. The same applies to the cluster C8 and the cluster C10. By combining the cluster C4 and the cluster C6, the total number of clusters and loadlock chambers be reduced.

### <Clusters C1, C2, C3, and C4+C6>

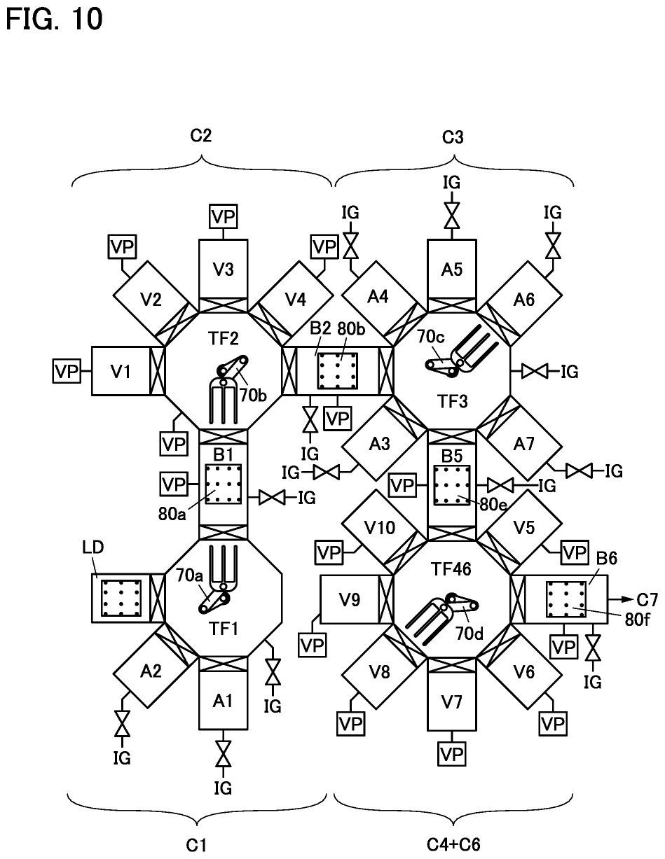

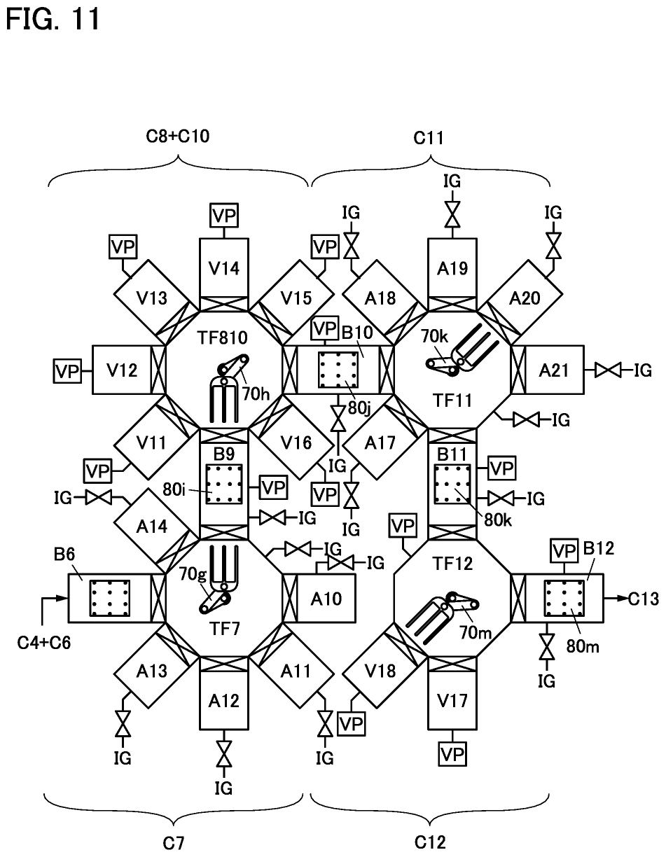

FIG. 10 is a top view illustrating the clusters C1, C2, C3, and C4+C6. The connections between the clusters C1 to C3 are similar to those illustrated in FIG. 2. The cluster C3 is connected to the cluster C4+C6 through the loadlock chamber B5. The cluster C4+C6 is connected to the cluster C7 (see FIG. 11) through the loadlock chamber B6.

The cluster C4+C6 includes a transfer chamber TF46 and the vacuum process apparatuses V. As the vacuum process apparatuses V (vacuum process apparatuses V5 to V10), an evaporation apparatus, a sputtering apparatus, a CVD apparatus, an ALD apparatus, an etching apparatus, an ashing apparatus, or the like can be used, for example.

The loadlock chambers B5 and B6 are each provided with a valve for introducing an inert gas and the vacuum pump VP. Thus, the loadlock chambers B5 and B6 can be controlled so as to be in a reduced pressure or an inert gas atmosphere.

The transfer chamber TF46 is connected to the loadlock chamber B5 through a gate valve. The transfer chamber TF46 is also connected to the loadlock chamber B6 through another gate valve. The transfer chamber TF46 is provided with the carrying device 70d. The carrying device 70d can carry the substrate from the loadlock chamber B5 to the vacuum process apparatus V. In addition, the carrying device 70d can carry out the substrate taken from the vacuum process apparatus V into the loadlock chamber B6.

### <Clusters C7, C8+C10, C11, and C12>

FIG. 11 is a top view illustrating the clusters C7, C8+C10, C11, and C12. The connection between the clusters C11 and C12 is similar to that illustrated in FIG. 4. The cluster C7 is connected to the cluster C8+C10 through the loadlock chamber B9. The cluster C8+C10 is connected to the cluster C11 through the loadlock chamber B10.

The cluster C8+C10 includes a transfer chamber TF810 and the vacuum process apparatuses V. As the vacuum process apparatuses V (the vacuum process apparatuses V11 to V16), an evaporation apparatus, a sputtering apparatus, a CVD apparatus, an ALD apparatus, an etching apparatus, an ashing apparatus, or the like can be used, for example.

The loadlock chambers B9 and B10 are each provided with a valve for introducing an inert gas and the vacuum pump VP. Thus, the loadlock chambers B9 and B10 can be controlled so as to be in a reduced pressure or an inert gas atmosphere.

The transfer chamber TF810 is connected to the loadlock chamber B9 through a gate valve. The transfer chamber TF810 is also connected to the loadlock chamber B10 through another gate valve. The transfer chamber TF810 is provided with the carrying device 70h. The carrying device 70h can carry the substrate from the loadlock chamber B9 into the vacuum process apparatus V. The carrying device 70h can carry out the substrate taken from the vacuum process apparatus V into the loadlock chamber B10.

### <Clusters C13 and C14>

The structures of the clusters C13 and C14 can be similar to those illustrated in FIG. 5.

### <Structure of Deposition Apparatus>

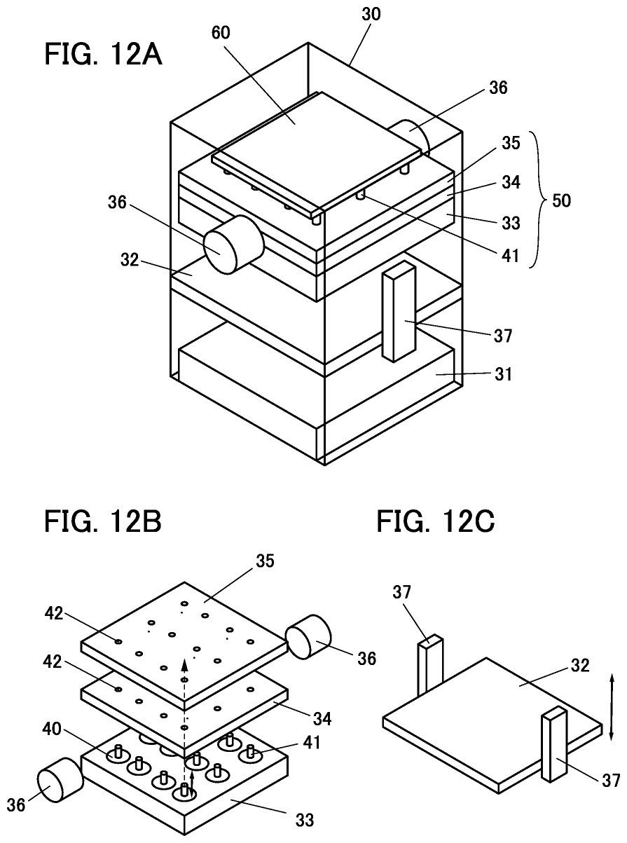

FIG. 12A is a diagram illustrating the vacuum process apparatus V (face-down deposition apparatus) in which a substrate is placed with a deposition surface facing downward; here, a deposition apparatus 30 is illustrated as an example. Note that for the sake of clarity, a chamber wall is illustrated as a transparent view and a gate valve is not illustrated in the diagram.

The deposition apparatus 30 includes a deposition material supply unit 31, a mask unit 32, and a stage 50 where a substrate 60 is to be set. The deposition material supply unit 31 is provided with, for example, an evaporation source when the deposition apparatus 30 is an evaporation apparatus. Alternatively, the deposition material supply unit 31 is provided with a target (cathode) when the deposition apparatus 30 is a sputtering apparatus.

FIG. 12B is an exploded view illustrating details of the stage 50. The stage 50 has a structure in which a cylinder unit 33, an electromagnet unit 34, and an electrostatic adsorption unit 35 overlap in this order. The cylinder unit 33 includes a plurality of cylinders 40. The cylinders have a function of moving up and down cylinder rods connected to pusher pins 41.

The pusher pins 41 are inserted into through holes 42 formed in the electromagnet unit 34 and the electrostatic adsorption unit 35. The operation of the cylinders 40 allows tips of the pusher pins 41 to touch the substrate 60 so as to move up and down the substrate 60. FIG. 12A illustrates a state in which the substrate 60 is placed over the raised pusher pins 41.

Note that one pusher pin 41 is connected to one cylinder 40 in the structure illustrated in FIG. 12B; however, a plurality of pusher pins 41 may be connected to one cylinder 40. The number of the pusher pins 41 and the position thereof may be determined as appropriate so as not to interfere with a hand portion of the carrying device.

The electromagnet unit 34 can generate magnetic force when receiving power and has a function of closely attaching a mask jig described later to the substrate 60. Note that the mask jig is preferably formed using a ferromagnetic material such as stainless steel.

The electrostatic adsorption unit 35 has the following function: voltage is applied to the substrate 60 from an internal electrode of the electrostatic adsorption unit 35, so that electric charge in the electrostatic adsorption unit 35 and electric charge in the substrate 60 attract each other to cause adsorption. Thus, unlike vacuum adsorption mechanism, the electrostatic adsorption unit can adsorb and hold the substrate even in vacuum. It is preferable that the electrostatic adsorption unit be formed using dielectric ceramic or the like and not contain a ferromagnetic body.

Rotation mechanisms 36 such as motors are connected to a first edge surface of the stage 50 and a second edge surface facing the first edge surface, allowing the stage 50 to be vertically reversed. Here, the combination of the stage 50 and the rotation mechanisms 36 can be referred to as a substrate reversing device.

As illustrated in FIG. 12C, the mask unit 32 is provided with lifting mechanisms 37, which are connected to a first edge surface of the mask unit 32 and a second edge surface facing the first edge surface. The mask unit 32 includes a mask jig and an alignment mechanism and can closely attach the mask jig to the substrate 60 with alignment.

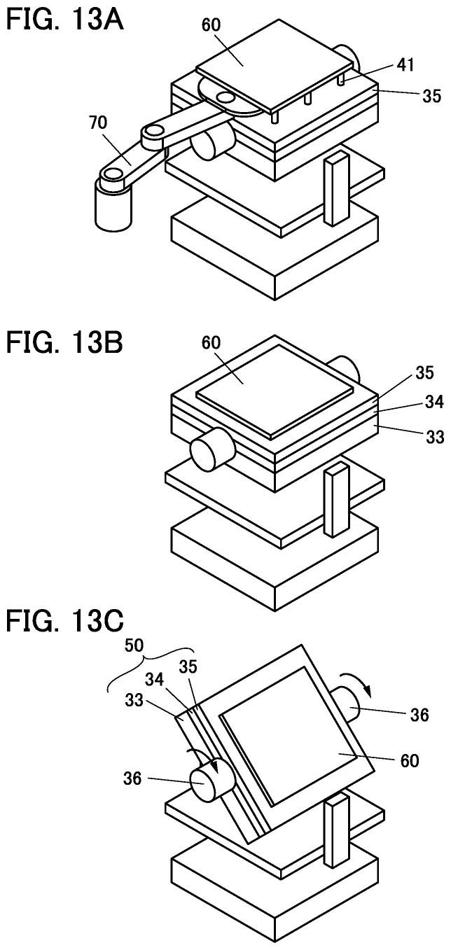

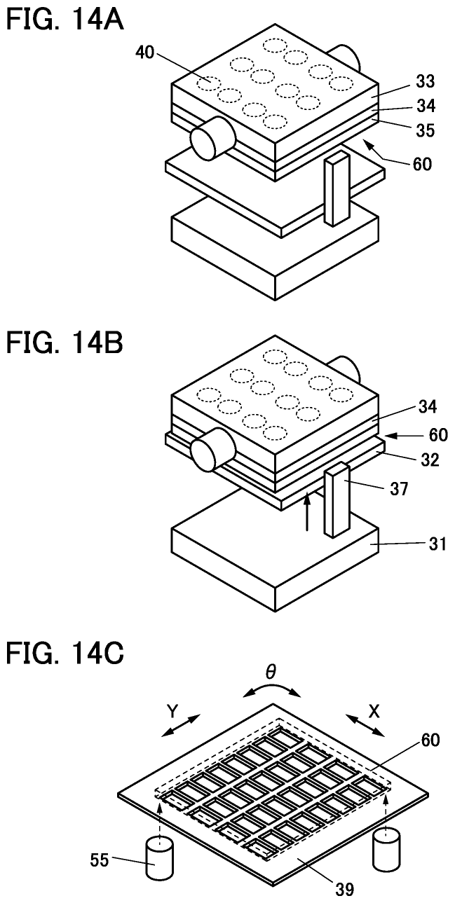

Next, steps from transferring of the substrate to the deposition apparatus 30 to deposition are described with reference to FIG. 13A to FIG. 14B. Note that for the sake of clarity, chamber walls, gate valves, and the like are not illustrated in FIG. 13A to FIG. 14B.

First, with the electrostatic adsorption unit 35 of the stage 50 facing upward, the substrate 60 placed over the hand portion of the carrying device 70 is moved above the electrostatic adsorption unit 35. Then, the substrate 60 is raised by the pusher pins 41. Alternatively, the hand portion of the carrying device 70 is lowered to place the substrate 60 over the raised pusher pins 41 (see FIG. 13A).

Next, the pusher pins 41 are lowered so that the substrate 60 is placed over the electrostatic adsorption unit 35, and the electrostatic adsorption unit 35 is operated to adsorb the substrate 60 (see FIG. 13B).

Then, the stage 50 is rotated by the rotation mechanisms 36 to reverse the substrate 60 (see FIG. 13C and FIG. 14A).

Then, the mask unit 32 is raised by the lifting mechanisms 37, and the mask jig is aligned to touch the substrate 60. After that, power is applied to the electromagnet unit 34, whereby the mask jig is closely attached to the substrate 60 (see FIG. 14B).

FIG. 14C illustrates a mask jig 39 included in the mask unit 32. A circuit and the like are provided on the surface of the substrate 60 in advance, and the substrate 60 is attached closely to the mask jig 39 so as to avoid deposition in an unnecessary area. The mask unit 32 includes an alignment mechanism including a camera 55 and can adjust the positions (X, Y, and 0 directions) between a portion to be deposited on the substrate 60 and an opening portion of the mask jig 39.

After the deposition step is performed in the state illustrated in FIG. 14B, the operation is performed in a reverse order of the above, whereby the substrate can be taken out.

The substrate reversing device only needs to be provided in a deposition apparatus (face-down deposition apparatus) that requires the substrate to be reversed. Thus, there is no need to provide a substrate reversing mechanism in a substrate carrying device or a loadlock chamber, resulting in a reduction in the costs of the whole device. This is particularly effective in manufacturing equipment like the manufacturing equipment of one embodiment of the present invention, which includes both a face-down apparatus (a deposition apparatus) and a face-up apparatus (e.g., a deposition apparatus and a lithography apparatus).

This embodiment can be implemented in an appropriate combination with the structures described in the other embodiments.

### Embodiment 2

This embodiment will describe a specific example for manufacturing a light-emitting element (organic EL element) with the use of manufacturing equipment for a light-emitting device that is one embodiment of the present invention.

In this specification and the like, a device formed using a metal mask or an FMM (fine metal mask or high-resolution metal mask) is sometimes referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned is sometimes referred to as an SBS (Side By Side) structure. In this specification and the like, a light-emitting device capable of emitting white light may be referred to as a white-light-emitting device. Note that a white-light-emitting device that is combined with coloring layers (e.g., color filters) can be a full-color display device.

Structures of light-emitting devices can be classified roughly into a single structure and a tandem structure. A device having a single structure includes one light-emitting unit between a pair of electrodes, and the light-emitting unit preferably includes one or more light-emitting layers. To obtain white light emission, two or more light-emitting layers are selected such that their emission colors are complementary to each other. For example, when emission colors of a first light-emitting layer and a second light-emitting layer are complementary colors, the light-emitting device can be configured to emit white light as a whole. The same applies to a light-emitting device including three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the plurality of light-emitting units can be combined to be white light. Note that a structure for obtaining white light emission is similar to a structure in the case of a single structure. In the device having a tandem structure, it is suitable that an intermediate layer such as a charge-generation layer is provided between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is preferable in terms of lower manufacturing cost or higher manufacturing yield because the manufacturing process of the white-light-emitting device is simpler than that of a light-emitting device having an SBS structure.

The device with a tandem structure may include light-emitting layers emitting light of the same color (e.g., BB, GG, or RR). The tandem structure emitting light from a plurality of layers requires high voltage for light emission but achieves the same emission intensity as a single structure with a smaller current value. Thus, with the tandem structure, current stress on each light-emitting unit can be reduced and the element lifetime can be extended.

### Structure Example

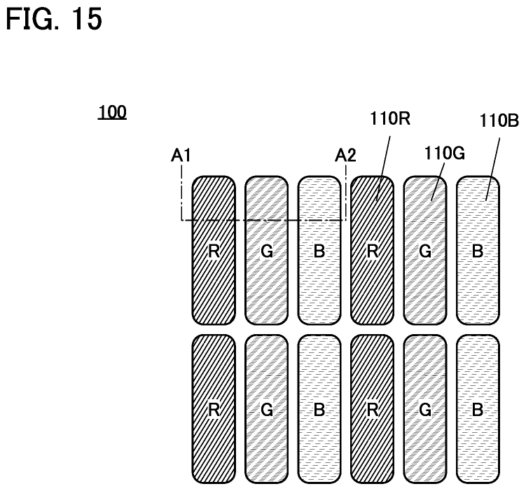

FIG. 15 is a schematic top view of a display device 100 fabricated using manufacturing equipment for a light-emitting device of one embodiment of the present invention. The display device 100 includes a plurality of light-emitting elements 110R exhibiting red, a plurality of light-emitting elements 110G exhibiting green, and a plurality of light-emitting elements 110B exhibiting blue. In FIG. 15, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 15 illustrates what is called a stripe arrangement, in which the light-emitting elements of the same color are arranged in one direction. Note that the arrangement method of the light-emitting elements is not limited thereto; another arrangement method such as a delta arrangement, a zigzag arrangement, or a PenTile arrangement may also be used.

As each of the light-emitting elements 110R, the light-emitting elements 110G, and the light-emitting elements 110B, an EL element such as an OLED (Organic Light Emitting Diode) or a QLED (Quantum-dot Light Emitting Diode) is preferably used. As a light-emitting substance contained in the EL element, a substance that emits fluorescent light (a fluorescent material), a substance that emits phosphorescent light (a phosphorescent material), an inorganic compound (e.g., a quantum dot material), a substance that exhibits thermally activated delayed fluorescence (a thermally activated delayed fluorescent (TADF) material), and the like can be given.

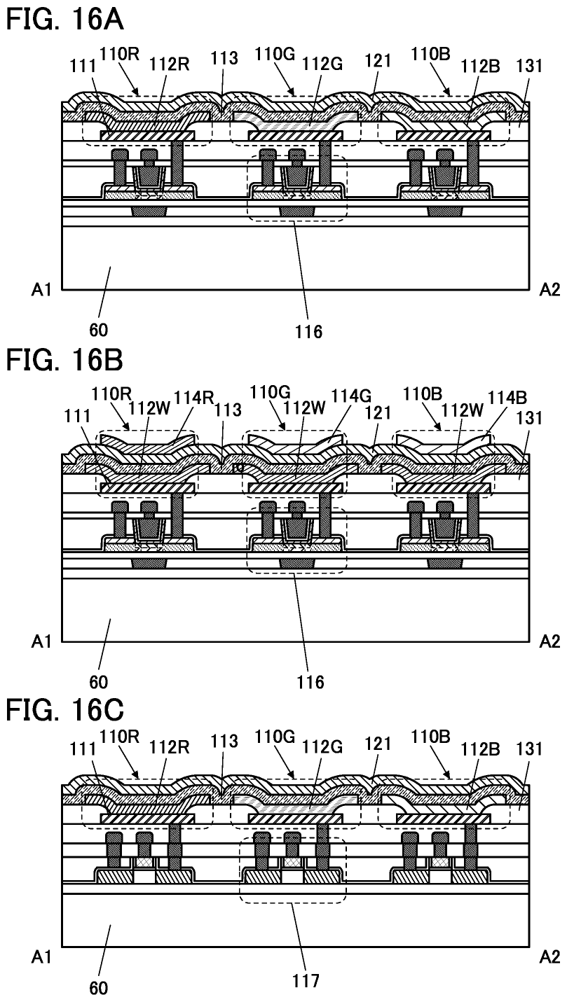

FIG. 16A is a cross-sectional schematic view taken along dashed-dotted line A1-A2 in FIG. 15.

FIG. 16A illustrates cross sections of the light-emitting element 110R, the light-emitting element 110G, and the light-emitting element 110B. The light-emitting element 110R, the light-emitting element 110G, and the light-emitting element 110B are provided over a pixel circuit and each include a pixel electrode 111 and a common electrode 113.

The light-emitting element 110R includes an EL layer 112R between the pixel electrode 111 and the common electrode 113. The EL layer 112R contains at least a light-emitting organic compound that emits light having a peak in the red wavelength range. An EL layer 112G included in the light-emitting element 110G contains at least a light-emitting organic compound that emits light having a peak in the green wavelength range. An EL layer 112B included in the light-emitting element 110B contains at least a light-emitting organic compound that emits light having a peak in the blue wavelength range. Note that a structure in which the EL layer 112R, the EL layer 112G, and the EL layer 112B emit light of different colors may be referred to as an SBS (Side By Side) structure.

The EL layer 112R, the EL layer 112G, and the EL layer 112B may each include one or more of an electron-injection layer, an electron-transport layer, a hole-injection layer, and a hole-transport layer in addition to the layer containing a light-emitting organic compound (light-emitting layer). Each of the EL layer 112R, the EL layer 112G, and the EL layer 112B may also have a tandem structure including a plurality of light-emitting layers that emit light of the same color.

The pixel electrode 111 is provided in each of the light-emitting elements. The common electrode 113 is provided as a continuous layer shared by the light-emitting elements. A conductive film with a property of transmitting visible light is used for either one of the pixel electrode 111 and the common electrode 113, and a conductive film with a property of reflecting visible light is used for the other. When the pixel electrodes 111 are light-transmitting electrodes and the common electrode 113 is a reflective electrode, a bottom-emission display device can be obtained; in contrast, when the pixel electrodes 111 are reflective electrodes and the common electrode 113 is a light-transmitting electrode, a top-emission display device can be obtained. Note that when both the pixel electrode 111 and the common electrode 113 have a light-transmitting property, the display device can have a dual emission structure. In this embodiment, an example of manufacturing a top-emission display device is described.

An insulating layer 131 is provided to cover end portions of the pixel electrode 111. The end portion of the insulating layer 131 is preferably tapered.

The EL layer 112R, the EL layer 112G, and the EL layer 112B each include a region in contact with the top surface of the pixel electrode 111 and a region in contact with a surface of the insulating layer 131. End portions of the EL layer 112R, the EL layer 112G, and the EL layer 112B are positioned over the insulating layer 131.

As illustrated in FIG. 16A, there is a gap between the two EL layers of the light-emitting elements with different colors. In this manner, the EL layer 112R, the EL layer 112G, and the EL layer 112B are preferably provided so as not to be in contact with each other. This can suitably prevent unintended light emission from being caused by a current flowing through two adjacent EL layers. As a result, the contrast can be increased, so that a display device with high display quality can be achieved.

A protective layer 121 is provided over the common electrode 113 so as to cover the light-emitting element 110R, the light-emitting element 110G, and the light-emitting element 110B. The protective layer 121 has a function of preventing diffusion of impurities into the light-emitting elements from above. Alternatively, the protective layer 121 has a function of capturing (also called gettering) impurities (such as water and hydrogen typically) that may enter the light-emitting elements.

The protective layer 121 can have, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 121. Note that the protective layer 121 is suitably formed using an ALD apparatus shown in Embodiment 1. In the case where the protective layer 121 is formed using the ALD apparatus, for example, an aluminum oxide film is preferably used.

The pixel electrode 111 is electrically connected to one of a source and a drain of a transistor 116. Here, the transistor 116 is included in a pixel circuit. A transistor including a metal oxide in a channel formation region (hereinafter, an OS transistor) can be used as the transistor 116, for example. The OS transistor has higher mobility than amorphous silicon and has excellent electrical characteristics. In addition, a crystallization step needed in the manufacturing process using polycrystalline silicon is not necessary for the OS transistor, and the OS transistor can be fabricated with high uniformity in a deposition step or the like.

As a semiconductor material used for an OS transistor, a metal oxide whose energy gap is greater than or equal to 2 eV, preferably greater than or equal to 2.5 eV, further preferably greater than or equal to 3 eV can be used.

In an OS transistor, a semiconductor layer has a large energy gap, and thus the OS transistor has an extremely low off-state current of several yoctoamperes per micrometer (current per micrometer of a channel width). An OS transistor has features such that impact ionization, an avalanche breakdown, a short-channel effect, or the like does not occur, which are different from those of a transistor including silicon in the channel formation region (hereinafter, a Si transistor); thus, a highly reliable circuit having high withstand voltage can be formed. Moreover, variation in electrical characteristics due to crystallinity unevenness, which is caused in Si transistors, is less likely to occur in OS transistors.

A semiconductor layer in an OS transistor can be, for example, a film represented by an In—M—Zn-based oxide that contains indium, zinc, and M (M is one or more of metals such as aluminum, titanium, gallium, germanium, yttrium, zirconium, lanthanum, cerium, tin, neodymium, and hafnium). The In—M—Zn-based oxide can be typically formed by a sputtering method. Alternatively, the In—M—Zn-based oxide can be formed by an ALD (Atomic layer deposition) method.

It is preferable that the atomic ratio of metal elements in a sputtering target used to form an In—M—Zn oxide by a sputtering method satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, or In:M:Zn=5:1:8. Note that the atomic ratio in the formed semiconductor layer varies from the above atomic ratio of metal elements of the sputtering target in a range of ±40%.

An oxide semiconductor with low carrier density is used for the semiconductor layer. For example, for the semiconductor layer, an oxide semiconductor whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³ can be used. Such an oxide semiconductor is referred to as a highly purified intrinsic or substantially highly purified intrinsic oxide semiconductor. The oxide semiconductor has a low density of defect states and can thus be referred to as an oxide semiconductor having stable characteristics.

Note that the composition is not limited to those described above, and an oxide semiconductor having an appropriate composition can be used depending on required semiconductor characteristics and electrical characteristics (e.g., field-effect mobility and threshold voltage) of the transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

Although FIG. 16A illustrates an exemplary structure in which the light-emitting layers of the R, G, and B light-emitting elements are different from each other, one embodiment of the present invention is not limited thereto. For example, as illustrated in FIG. 16B, a coloring method may be employed in which the light-emitting elements 110R, 110G, and 110B are formed by providing EL layers 112W that emit white light and providing coloring layers 114R (red), 114G (green), and 114B (blue) that overlap with the EL layers 112W.

The EL layer 112W can have a tandem structure in which EL layers emitting R, G, and B light are connected in series, for example. Alternatively, a structure in which light-emitting layers emitting R, G, and B light are connected in series may be used. As the coloring layers 114R, 114G, and 114B, for example, red, green, and blue color filters can be used.

As illustrated in FIG. 16C, a pixel circuit may be formed with a Si transistor (a transistor 117) included in the substrate 60, and one of a source and a drain of the transistor 117 may be electrically connected to the pixel electrode 111.

Amorphous silicon, microcrystalline silicon, polycrystalline silicon, single crystal silicon, or the like can be used for the channel formation region of the Si transistor. Note that polycrystalline silicon is preferably used in the case where a transistor is provided on an insulating surface of a glass substrate or the like.

High-quality polycrystalline silicon can be obtained easily by using a laser crystallization step or the like, and a transistor with high mobility can be formed. In addition, the high-quality polycrystalline silicon can be also obtained by a solid-phase growth method in which a metal catalyst such as nickel or palladium is added to amorphous silicon and then heated. Furthermore, to further enhance crystallinity, the polycrystalline silicon formed by the solid-phase growth method using a metal catalyst may be subjected to laser irradiation. Note that the metal catalyst remains in the polycrystalline silicon and worsens electrical characteristics of the transistor; therefore, it is preferable to provide a region to which phosphorus, a noble gas, or the like is added to a region other than the channel formation region, so that the region captures the metal catalyst.

### <Example of Manufacturing Method>

Described below is an example of a manufacturing method of a light-emitting device with the manufacturing equipment of one embodiment of the present invention. Here, description is made using an example of the light-emitting device included in the display device 100 described in the above structure example.

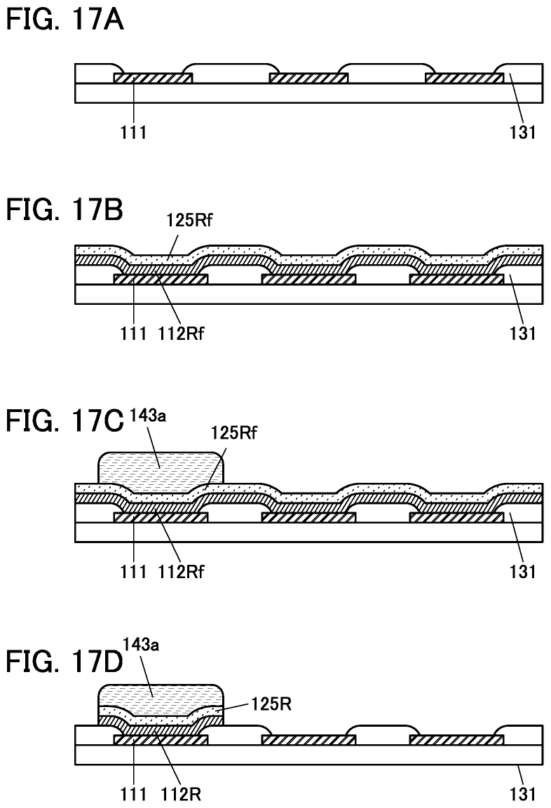

FIG. 17A to FIG. 19E are schematic cross-sectional views in steps of the manufacturing method of the light-emitting device described below. Note that the transistor 116 that is a component of the pixel circuit illustrated in FIG. 16A is omitted in FIG. 17A to FIG. 19E.

Thin films constituting the display device (insulating films, semiconductor films, conductive films, and the like) can be formed by a sputtering method, a chemical vapor deposition (CVD) method, a vacuum evaporation method, an atomic layer deposition (ALD) method, or the like. Examples of the CVD method include a plasma-enhanced chemical vapor deposition (PECVD: Plasma Enhanced CVD) method and a thermal CVD method. An example of a thermal CVD method is a metal organic chemical vapor deposition (MOCVD: Metal Organic CVD) method. The manufacturing equipment of one embodiment of the present invention can include an apparatus for forming thin films by the above method.

A method such as spin coating, dipping, spray coating, ink-jetting, dispensing, screen printing, offset printing, a doctor knife method, slit coating, roll coating, curtain coating, or knife coating can be employed for formation of the thin films constituting the display device (insulating films, semiconductor films, conductive films, and the like) and application of a resin or the like used for a lithography step. The manufacturing equipment of one embodiment of the present invention can include an apparatus for forming thin films by the above method. In addition, the manufacturing equipment of one embodiment of the present invention can include an apparatus for applying a resin by the above method.

The thin films constituting the display device can be processed by a photolithography method or the like. Alternatively, the thin films may be processed by a nanoimprinting method. A method in which island-shaped thin films are directly formed by a deposition method using a blocking mask may also be used.

There are two typical methods for processing a thin film using a photolithography method. In one of the methods, a resist mask is formed over a thin film that is to be processed, the thin film is processed by etching or the like, and then the resist mask is removed. In the other method, a photosensitive thin film is deposited and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. It is preferable to use extreme ultraviolet light, X-rays, or an electron beam because extremely minute processing can be performed. Note that a photomask is not needed when exposure is performed by scanning with a beam such as an electron beam.

For etching of thin films, a dry etching method, a wet etching method, or the like can be used. The manufacturing equipment of one embodiment of the present invention can include an apparatus for processing thin films by the above method.

### <Preparation of Substrate 60>

As the substrate 60, a substrate having at least heat resistance high enough to withstand later heat treatment can be used. In the case where an insulating substrate is used as the substrate 60, a glass substrate, a quartz substrate, a sapphire substrate, a ceramics substrate, an organic resin substrate, or the like can be used. Alternatively, a single crystal semiconductor substrate using silicon or silicon carbide, a polycrystalline semiconductor substrate, a compound semiconductor substrate of silicon germanium or the like, a semiconductor substrate such as an SOI substrate, or the like can be used.

As the substrate 60, it is particularly preferable to use the semiconductor substrate or the insulating substrate over which a semiconductor circuit including a semiconductor element such as a transistor is formed. With the semiconductor circuit, a pixel circuit, a gate line driver circuit (a gate driver), a source line driver circuit (a source driver), or the like is preferably formed. In addition to the above, an arithmetic circuit, a memory circuit, or the like may be formed.

### <Formation of Pixel Circuit and Pixel Electrode 111>

Next, a plurality of pixel circuits are formed over the substrate 60, and the pixel electrode 111 is formed for each of the pixel circuits. First, a conductive film to be the pixel electrodes 111 is formed, a resist mask is formed by a photolithography method, and an unnecessary portion of the conductive film is removed by etching. After that, the resist mask is removed, so that the pixel electrodes 111 can be formed.

It is preferable to use, for the pixel electrodes 111, a material (e.g., silver or aluminum) having reflectance as high as possible in the whole wavelength range of visible light. The pixel electrodes 111 formed using the material can be referred to as electrodes having a light-reflecting property. This can increase color reproducibility as well as light extraction efficiency of the light-emitting elements.

### <Formation of Insulating Layer 131>

Subsequently, the insulating layer 131 is formed to cover end portions of the pixel electrodes 111 (see FIG. 17A). An organic insulating film or an inorganic insulating film can be used for the insulating layer 131. The end portion of the insulating layer 131 is preferably tapered to improve step coverage with an EL film formed later. In particular, when an organic insulating film is used, a photosensitive material is preferably used so that the shape of the end portions can be easily controlled by the conditions of light exposure and development.

### <Formation of EL Film 112Rf>

Subsequently, an EL film 112Rf to be the EL layer 112R later is formed over the pixel electrodes 111 and the insulating layer 131.

The EL film 112Rf includes at least a film containing a red-light-emitting organic compound. A structure may be employed in which an electron-injection layer, an electron-transport layer, a charge-generation layer, a hole-transport layer, and a hole-injection layer are stacked in addition to the above. The EL film 112Rf can be formed by an evaporation method or a sputtering method, for example. Without limitation to this, the above-described deposition method can be used as appropriate.

### <Formation of Protective Film 125Rf>

Next, a protective film 125Rf to be a protective layer 125R later is formed over the EL film 112Rf (see FIG. 17B).

The protective layer 125R is a tentative protective layer, which is also called a sacrifice layer, used for preventing the EL layer 112R from being degraded and vanishing in a manufacturing process of the organic EL elements. The protective film 125Rf is preferably formed by a deposition method that has high barrier property against moisture or the like and is less likely to give damage to an organic compound during deposition. Furthermore, the protective film 125Rf is preferably formed using a material for which an etchant less likely to give damage to the organic compound in an etching step is acceptable. The protective film 125Rf can be formed using an organic film or an inorganic film such as a metal film, an alloy film, a metal oxide film, a semiconductor film, or an inorganic insulating film.

<Formation of Resist Mask 143a>

Next, a resist mask 143a is formed over the pixel electrode 111 corresponding to the light-emitting element 110R (see FIG. 17C). The resist mask 143a can be formed by a lithography step.

### <Formation of EL Layer 112R and Protective Layer 125R>

Then, the protective film 125Rf and the EL film 112Rf are etched with the resist mask 143a used as a mask, so that the protective layer 125R and the EL layer 112R are formed to have an island shape (see FIG. 17D). A dry etching method or a wet etching method can be used for the etching step. After that, the resist mask 143a is removed by ashing or using a resist stripper.

<Formation of EL film 112Gf>

Subsequently, an EL film 112Gf to be the EL layer 112G later is formed over the exposed pixel electrodes 111 and insulating layer 131, and the protective layer 125R.

The EL film 112Gf includes at least a film containing a green-light-emitting organic compound. A structure may be employed in which an electron-injection layer, an electron-transport layer, a charge-generation layer, a hole-transport layer, and a hole-injection layer are stacked in addition to the above.

### <Formation of Protective Film 125Gf>

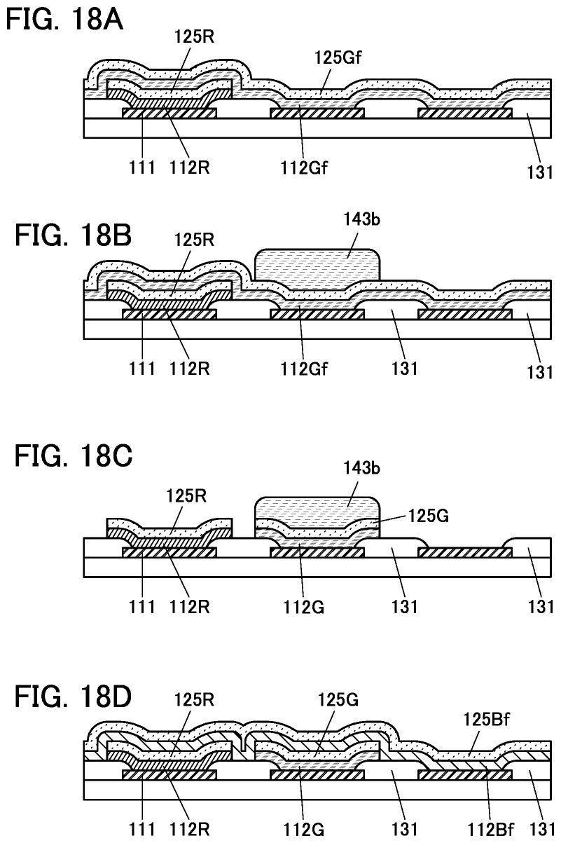

Then, a protective film 125Gf to be a protective layer 125G later is formed over the EL film 112Gf (see FIG. 18A). The protective film 125Gf can be formed using a material similar to that of the protective film 125Rf.

<Formation of Resist Mask 143b>

Next, a resist mask 143b is formed over the pixel electrode 111 corresponding to the light-emitting element 110G (see FIG. 18B). The resist mask 143b can be formed by a lithography step.

### <Formation of EL Layer 112G and Protective Layer 125G>

Then, the protective layer 125G and the EL film 112Gf are etched with the resist mask 143b used as a mask, so that the protective layer 125G and the EL layer 112G are formed to have an island shape (see FIG. 18C). A dry etching method or a wet etching method can be used for the etching step. After that, the resist mask 143b is removed by ashing or using a resist stripper.

### <Formation of EL Film 112Bf>

Subsequently, an EL film 112Bf to be the EL layer 112B later is formed over the exposed pixel electrode 111 and insulating layer 131, and the protective layers 125R and 125G.

The EL film 112Bf includes at least a film containing a blue-light-emitting organic compound. A structure may be employed in which an electron-injection layer, an electron-transport layer, a charge-generation layer, a hole-transport layer, and a hole-injection layer are stacked in addition to the above.

### <Formation of Protective Film 125Bf>

Next, a protective film 125Bf to be a protective layer 125B later is formed over the EL film 112Bf (see FIG. 18D). The protective film 125Bf can be formed using a material similar to that of the protective film 125Rf.

<Formation of Resist Mask 143c>

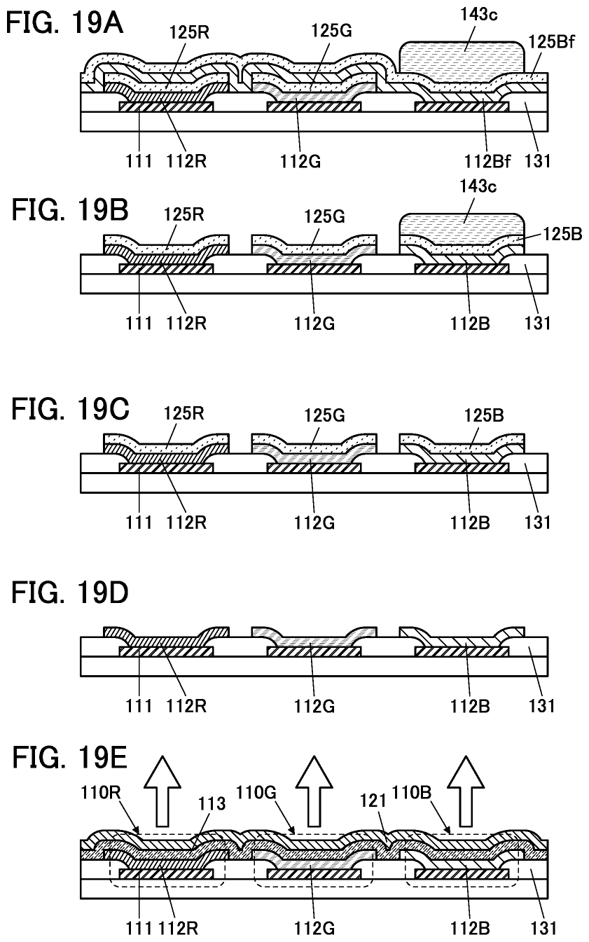

Next, a resist mask 143c is formed over the pixel electrode 111 corresponding to the light-emitting element 110B (see FIG. 19A). The resist mask 143c can be formed by a lithography step.

### <Formation of EL Layer 112B and Protective Layer 125B>

Then, the protective film 125Bf and the EL film 112Bf are etched with the resist mask 143c used as a mask, so that the protective layer 125B and the EL layer 112G are formed to have an island shape (see FIG. 19B). A dry etching method or a wet etching method can be used for the etching step. After that, the resist mask 143b is removed by ashing or using a resist stripper (see FIG. 19C).

### <Removal of Protective Layers 125R, 125G, and 125B>

Next, the protective layers 125R, 125G, and 125B are removed (see FIG. 19D). A wet etching method using an etchant suitable for the material of the protective layers is preferably used for the removal of the protective layers, for example.

### <Formation of Common Electrode>

Then, a conductive layer to be the common electrode 113 of the organic EL elements is formed over the EL layer 112R, the EL layer 112G, and the EL layer 112B that are exposed in the previous step and the insulating layer 131. For the common electrode 113, either one of a thin metal film that transmits light emitted from the light-emitting layer (e.g., an alloy of silver and magnesium) and a light-transmitting conductive film (e.g., indium tin oxide or an oxide containing one or more of indium, gallium, zinc, and the like) or a stack of these films can be used. The common electrode 113 formed using such a film can be referred to as an electrode having a light-transmitting property. For the step of forming the conductive layer to be the common electrode 113, an evaporation apparatus and/or a sputtering apparatus can be used, for example.

Note that before the formation of the common electrode 113, a layer having a function of any of an electron-injection layer, an electron-transport layer, a charge-generation layer, a hole-transport layer, and a hole-injection layer may be provided as a common layer over the EL layer 112R, the EL layer 112G, and the EL layer 112B, so that the reliability is improved.

When the electrodes having a light-reflecting property are included as the pixel electrodes 111 and the electrode having a light-transmitting property is included as the common electrode 113, light emitted from the light-emitting layers can be emitted to the outside through the common electrode 113. In other words, top emission light-emitting elements are formed.

### <Formation of Protective Layer>

Next, the protective layer 121 is formed over the common electrode 113 (FIG. 19E). A sputtering apparatus, a CVD apparatus, an ALD apparatus, or the like can be used for the step of forming the protective layer.

### <Example of Manufacturing Equipment>

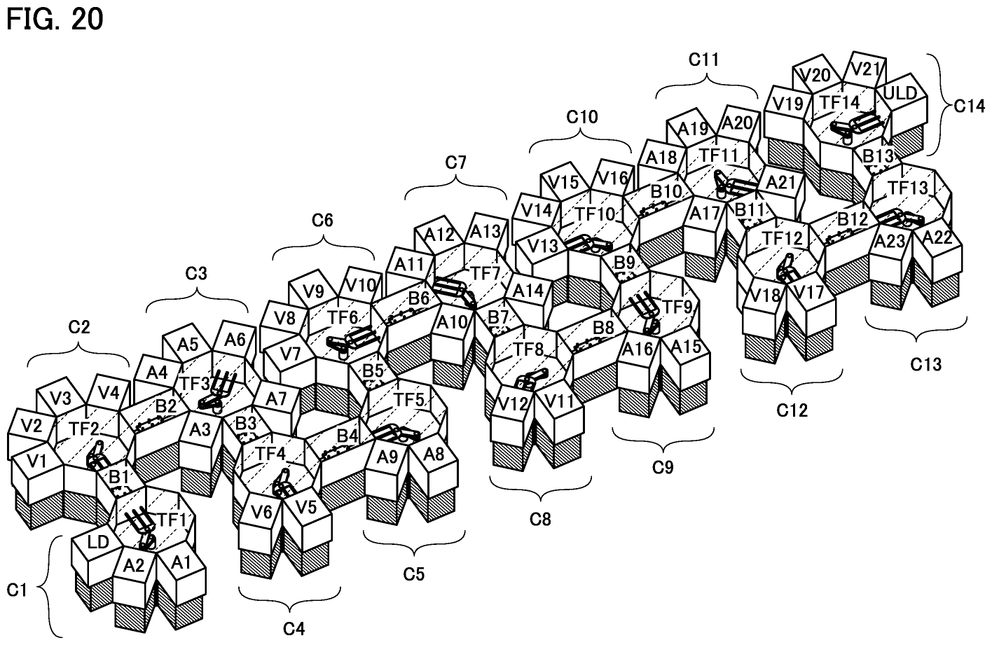

FIG. 20 illustrates an example of manufacturing equipment that can be used for the above-described steps from the formation of the EL film 112Rf to the formation of the protective layer 121. The basic structure of the manufacturing equipment illustrated in FIG. 20 is similar to that of the manufacturing equipment illustrated in FIG. 1.

The cluster C1 to the cluster C14 are specifically described below. FIG. 20 is a schematic perspective view of the whole of the manufacturing equipment, where utilities, gate valves, and the like are not illustrated. In the drawing, the insides of the transfer chambers TF1 to TF14 and the loadlock chambers B1 to B13 are made visible for the sake of clarity.

### <Cluster C1>

The cluster C1 includes the load chamber LD and the normal-pressure process apparatuses A1 and A2. The normal-pressure process apparatus A1 can be a cleaning apparatus, and the normal-pressure process apparatus A2 can be a baking apparatus. In the cluster C1, a cleaning step prior to deposition of the EL film 112Rf is performed.

### <Cluster C2>

The cluster C2 includes vacuum process apparatuses V1 to V4. The vacuum process apparatuses V1 to V4 are an evaporation apparatus for forming the EL film 112Rf and a deposition apparatus for forming the protective film 125Rf (e.g., an evaporation apparatus or an ALD apparatus). For example, the vacuum process apparatus V1 can be an apparatus for forming an organic compound layer to be a light-emitting layer (R). The vacuum process apparatuses V2 and V3 can each be assigned to an apparatus for forming an organic compound layer such as an electron-injection layer, an electron-transport layer, a charge-generation layer, a hole-transport layer, or a hole-injection layer. Furthermore, the vacuum process apparatus V4 can be assigned to an apparatus for forming the protective film 125Rf.

### <Cluster C3>

The cluster C3 includes the normal-pressure process apparatuses A3 to A7. The normal-pressure process apparatuses A3 to A7 can be apparatuses used for a lithography step. For example, the normal-pressure process apparatus A3 can be a resin (photoresist) application apparatus, the normal-pressure process apparatus A4 can be a pre-baking apparatus, the normal-pressure process apparatus A5 can be a light-exposure apparatus, the normal-pressure process apparatus A6 can be a developing apparatus, and the normal-pressure process apparatus A7 can be a post-baking apparatus. Alternatively, the normal-pressure process apparatus A5 may be a nanoimprint apparatus.

### <Cluster C4>

The cluster C4 includes the vacuum process apparatuses V5 and V6. The vacuum process apparatus V5 can be a dry etching apparatus for forming the EL layer 112R. The vacuum process apparatus V6 can be an ashing apparatus for removing a resist mask.

### <Cluster C5>

The cluster C5 includes the normal-pressure process apparatuses A8 and A9. The normal-pressure process apparatus A8 can be a cleaning apparatus, and the normal-pressure process apparatus A9 can be a baking apparatus. In the cluster C5, a cleaning step prior to deposition of the EL film 112Gf is performed.

### <Cluster C6>

The cluster C6 includes the vacuum process apparatuses V7 to V10. The vacuum process apparatuses V7 to V10 are an evaporation apparatus for forming the EL film 112Gf and a deposition apparatus (e.g., sputtering apparatus) for forming the protective film 125Gf. For example, the vacuum process apparatus V7 can be an apparatus for forming an organic compound layer to be a light-emitting layer (G). The vacuum process apparatuses V8 and V9 can each be assigned to an apparatus for forming an organic compound layer such as an electron-injection layer, an electron-transport layer, a charge-generation layer, a hole-transport layer, or a hole-injection layer. Furthermore, the vacuum process apparatus V10 can be assigned to an apparatus for forming the protective film 125Gf.

### <Cluster C7>

The cluster C7 includes the normal-pressure process apparatuses A10 to A14. The normal-pressure process apparatuses A10 to A14 can be apparatuses used for a lithography step. The apparatuses can be assigned in a manner similar to those of the cluster C3.

### <Cluster C8>

The cluster C8 includes the vacuum process apparatuses V11 and V12. The vacuum process apparatus V11 can be a dry etching apparatus for forming the EL layer 112G. The vacuum process apparatus V12 can be an ashing apparatus for removing a resist mask.

### <Cluster C9>

The cluster C9 includes the normal-pressure process apparatuses A15 and A16. The normal-pressure process apparatus A15 can be a cleaning apparatus, and the normal-pressure process apparatus A16 can be a baking apparatus. In the cluster C9, a cleaning step prior to deposition of the EL film 112Bf is performed.

### <Cluster C10>

The cluster C10 includes the vacuum process apparatuses V13 to V16. The vacuum process apparatuses V13 to V16 are an evaporation apparatus for forming the EL film 112Bf and a deposition apparatus (e.g., sputtering apparatus) for forming the protective film 125Bf. For example, the vacuum process apparatus V13 can be an apparatus for forming an organic compound layer to be a light-emitting layer (G). The vacuum process apparatuses V14 and V15 can be assigned to apparatuses for formation of organic compound layers such as an electron-injection layer, an electron-transport layer, a charge-generation layer, a hole-transport layer, and a hole-injection layer. Furthermore, the vacuum process apparatus V16 can be assigned to an apparatus for forming the protective film 125Bf.

### <Cluster C11>

The cluster C11 includes the normal-pressure process apparatuses A17 to A21. The normal-pressure process apparatuses A17 to A21 can be apparatuses used for a lithography step. The apparatuses can be assigned in a manner similar to those of the cluster C3.

### <Cluster C12>

The cluster C12 includes vacuum process apparatuses V17 and V18. The vacuum process apparatus V17 can be a dry etching apparatus for forming the EL layer 112B. The vacuum process apparatus V18 can be an ashing apparatus for removing a resist mask.

### <Cluster C13>

The cluster C13 includes the normal-pressure process apparatuses A22 and A23. The normal-pressure process apparatus A22 can be a wet etching apparatus, and the normal-pressure process apparatus A23 can be a baking apparatus. In the cluster C9, etching steps of the protective layers 125R, 125G, and 125B are performed.

### <Cluster C14>

The cluster C14 includes the vacuum process apparatuses V19 to V21 and the unload chamber ULD. The vacuum process apparatus V19 can be assigned to an apparatus (e.g., an evaporation apparatus) for forming an organic compound layer such as an electron-injection layer, an electron-transport layer, a charge-generation layer, a hole-transport layer, or a hole-injection layer. The vacuum process apparatus V20 can be a deposition apparatus (e.g., a sputtering apparatus) for forming the common electrode 113. The vacuum process apparatus V21 can be a deposition apparatus (e.g., a sputtering apparatus) for forming the protective layer 121. Alternatively, another vacuum process apparatus V may be provided and a plurality of different deposition apparatuses (such as an evaporation apparatus or an ALD apparatus) are provided to form the common electrode 113 and the protective layer 121 so as to have stacked films.

Steps using the manufacturing equipment illustrated in FIG. 20, processing apparatuses, and components corresponding to the above-described manufacturing method are summarized in Table 1. Note that carrying of the substrate into and out of the loadlock chamber and the apparatuses are not described.

TABLE 1

| | | Processing | |
|---|---|---|---|
| Step No. | Step | apparatus | Component |
| 1 | Cleaning | A1 | |
| 2 | Baking | A2 | |
| 3 | Deposition of organic compound layer | V1 | 112Rf |
| 4 | Deposition of organic compound layer | V2 | |
| | (light-emitting layer) | | |
| 5 | Deposition of organic compound layer | V3 | |
| 6 | Deposition of protective film | V4 | 125Rf |
| 7 | Application of photoresist | A3 | |
| 8 | Pre-baking | A4 | |
| 9 | Light exposure | A5 | |
| 10 | Developing | A6 | |
| 11 | Post-baking | A7 | |
| 12 | Etching of protective film | V5 | 125R |
| 13 | Etching of organic compound layer | V5 | 112R |
| 14 | Ashing of resist mask | V6 | |
| 15 | Cleaning | A8 | |
| 16 | Baking | A9 | |
| 17 | Deposition of organic compound layer | V7 | 112Gf |
| 18 | Deposition of organic compound layer | V8 | |
| | (light-emitting layer) | | |
| 19 | Deposition of organic compound layer | V9 | |
| 20 | Deposition of protective film | V10 | 125Gf |
| 21 | Application of photoresist | A10 | |
| 22 | Pre-baking | A11 | |
| 23 | Light exposure | A12 | |
| 24 | Developing | A13 | |
| 25 | Post-baking | A14 | |
| 26 | Etching of protective film | V11 | 125Gf |
| 27 | Etching of organic compound layer | V11 | 112Gf |
| 28 | Ashing of resist mask | V12 | |
| 29 | Cleaning | A15 | |
| 30 | Baking | A16 | |
| 31 | Deposition of organic compound layer | V13 | 112Bf |
| 32 | Deposition of organic compound layer | V14 | |
| | (light-emitting layer) | | |
| 33 | Deposition of organic compound layer | V15 | |
| 34 | Deposition of protective film | V16 | 125Bf |
| 35 | Application of photoresist | A17 | |
| 36 | Pre-baking | A18 | |
| 37 | Light exposure | A19 | |
| 38 | Developing | A20 | |
| 39 | Post-baking | A21 | |
| 40 | Etching of protective film | V17 | 125Bf |
| 41 | Etching of organic compound layer | V17 | 112Bf |
| 42 | Ashing of resist mask | V18 | |
| 43 | Etching (removal) of protective film | A22 | |
| 44 | Baking | A23 | |
| 45 | Deposition of organic compound layer | V19 | |
| 46 | Deposition of common electrode | V20 | 113 |
| 47 | Deposition of protective film | V21 | 121 |

The manufacturing equipment of one embodiment of the present invention has a function of performing Step No. 1 to Step No. 47 in Table 1 automatically.

This embodiment can be implemented in an appropriate combination with the structures described in the other embodiments.

### REFERENCE NUMERALS

A1: normal-pressure process apparatus, A2: normal-pressure process apparatus, A3: normal-pressure process apparatus, A4: normal-pressure process apparatus, A5: normal-pressure process apparatus, A6: normal-pressure process apparatus, A7: normal-pressure process apparatus, A8: normal-pressure process apparatus, A9: normal-pressure process apparatus, A10: normal-pressure process apparatus, A11: normal-pressure process apparatus, A12: normal-pressure process apparatus, A13: normal-pressure process apparatus, A14: normal-pressure process apparatus, A15: normal-pressure process apparatus, A16: normal-pressure process apparatus, A17: normal-pressure process apparatus, A18: normal-pressure process apparatus, A19: normal-pressure process apparatus, A20: normal-pressure process apparatus, A21: normal-pressure process apparatus, A22: normal-pressure process apparatus, A23: normal-pressure process apparatus, B1: loadlock chamber, B2: loadlock chamber, B3: loadlock chamber, B4: loadlock chamber, B5: loadlock chamber, B6: loadlock chamber, B7: loadlock chamber, B8: loadlock chamber, B9: loadlock chamber, B10: loadlock chamber, B11: loadlock chamber, B12: loadlock chamber, B13: loadlock chamber, C1: cluster, C2: cluster, C3: cluster, C4: cluster, C5: cluster, C6: cluster, C7: cluster, C8: cluster, C9: cluster, C10: cluster, C11: cluster, C12: cluster, C13: cluster, C14: cluster, TF1: transfer chamber, TF2: transfer chamber, TF3: transfer chamber, TF4: transfer chamber, TF5: transfer chamber, TF6: transfer chamber, TF7: transfer chamber, TF8: transfer chamber, TF9: transfer chamber, TF10: transfer chamber, TF11: transfer chamber, TF12: transfer chamber, TF13: transfer chamber, TF14: transfer chamber, TF46: transfer chamber, TF810: transfer chamber, V1: vacuum process apparatus, V2: vacuum process apparatus, V3: vacuum process apparatus, V4: vacuum process apparatus, V5: vacuum process apparatus, V6: vacuum process apparatus, V7: vacuum process apparatus, V8: vacuum process apparatus, V9: vacuum process apparatus, V10: vacuum process apparatus, V11: vacuum process apparatus, V12: vacuum process apparatus, V13: vacuum process apparatus, V14: vacuum process apparatus, V15: vacuum process apparatus, V16: vacuum process apparatus, V17: vacuum process apparatus, V18: vacuum process apparatus, V19: vacuum process apparatus, V20: vacuum process apparatus, V21: vacuum process apparatus, 30: deposition apparatus, 31: deposition material supply unit, 32: mask unit, 33: cylinder unit, 34: electromagnet unit, 35: electrostatic adsorption unit, 36: rotation mechanism, 37: lifting mechanism, 39: mask jig, 40: cylinder, 41: pusher pin, 42: through hole, 50: stage, 55: camera, 60: substrate, 60a: substrate, 60b: substrate, 70: carrying device, 70a: carrying device, 70b: carrying device, 70c: carrying device, 70d: carrying device, 70e: carrying device, 70f: carrying device, 70g: carrying device, 70h: carrying device, 70i: carrying device, 70j: carrying device, 70k: carrying device, 70m: carrying device, 70n: carrying device, 70p: carrying device, 80a: stage, 80b: stage, 80c: stage, 80d: stage, 80e: stage, 80f: stage, 80g: stage, 80h: stage, 80i: stage, 80j: stage, 80k: stage, 80m: stage, 80n: stage, 100: display device, 110B: light-emitting element, 110G: light-emitting element, 110R: light-emitting element, 111: pixel electrode, 112B: EL layer, 112Bf: EL film, 112G: EL layer, 112Gf: EL film, 112R: EL layer, 112Rf: EL film, 112W: EL layer, 113: common electrode, 114B: coloring layer, 114G: coloring layer, 114R: coloring layer, 116: transistor, 117: transistor, 121: protective layer, 125B: protective layer, 125Bf: protective film, 125G: protective layer, 125Gf: protective film, 125R: protective layer, 125Rf: protective film, 131: insulating layer, 143a: resist mask, 143b: resist mask, 143c: resist mask

1. Manufacturing equipment for a light-emitting device, comprising:
first to eleventh clusters and first to tenth loadlock chambers,
wherein the first cluster is connected to the second cluster through the first loadlock chamber,
wherein the second cluster is connected to the third cluster through the second loadlock chamber,
wherein the third cluster is connected to the fourth cluster through the third loadlock chamber,
wherein the fourth cluster is connected to the fifth cluster through the fourth loadlock chamber,
wherein the fifth cluster is connected to the sixth cluster through the fifth loadlock chamber,
wherein the sixth cluster is connected to the seventh cluster through the sixth loadlock chamber,
wherein the seventh cluster is connected to the eighth cluster through the seventh loadlock chamber,
wherein the eighth cluster is connected to the ninth cluster through the eighth loadlock chamber,
wherein the ninth cluster is connected to the tenth cluster through the ninth loadlock chamber,
wherein the tenth cluster is connected to the eleventh cluster through the tenth loadlock chamber,
wherein pressures in the first cluster, the third cluster, the fourth cluster, the sixth cluster, the seventh cluster, the ninth cluster, and the eleventh cluster are controlled to reduced pressures,
wherein atmospheres in the second cluster, the fifth cluster, the eighth cluster, and the tenth cluster are controlled to inert gas atmospheres,
wherein the first cluster to the eleventh cluster each comprise a carrying device,
wherein the first cluster, the fourth cluster, the seventh cluster, and the eleventh cluster each comprise a face-up deposition apparatus and a face-down deposition apparatus,
wherein the third cluster, the sixth cluster, and the ninth cluster each comprise an etching apparatus,
wherein the second cluster, the fifth cluster, and the eighth cluster each comprise a plurality of apparatuses where a lithography step is performed,
wherein the tenth cluster comprises an etching apparatus, and
wherein the face-down deposition apparatus comprises a substrate reversing device.

2. The manufacturing equipment for a light-emitting device according to claim 1, further comprising:
a twelfth cluster and an eleventh loadlock chamber,
wherein the twelfth cluster is connected to the first cluster through the eleventh loadlock chamber,
wherein an atmosphere in the twelfth cluster is controlled to an inert gas atmosphere, and
wherein the twelfth cluster comprises a cleaning apparatus and a baking apparatus.

3. The manufacturing equipment for a light-emitting device according to claim 2,
wherein the twelfth cluster comprises a load chamber, and
wherein the eleventh cluster comprises an unload chamber.

4. The manufacturing equipment for a light-emitting device according to claim 1, further comprising:
a thirteenth cluster, a fourteenth cluster, a twelfth loadlock chamber, and a thirteenth loadlock chamber,
wherein the thirteenth cluster is connected to the third cluster through the third loadlock chamber,
wherein the thirteenth cluster is connected to the fourth cluster through the twelfth loadlock chamber,
wherein the fourteenth cluster is connected to the sixth cluster through the sixth loadlock chamber,
wherein the fourteenth cluster is connected to the seventh cluster through the thirteenth loadlock chamber,
wherein atmospheres in the thirteenth cluster and the fourteenth cluster are controlled to inert gas atmospheres, and
wherein the thirteenth cluster and the fourteenth cluster each comprise a cleaning apparatus and a baking apparatus.

5. The manufacturing equipment for a light-emitting device according to claim 1,
wherein the face-down deposition apparatus is one or more selected from an evaporation apparatus and a sputtering apparatus.

6. The manufacturing equipment for a light-emitting device according to claim 1,
wherein the face-up deposition apparatus is one or more selected from a CVD apparatus and an ALD apparatus.

7. The manufacturing equipment for a light-emitting device according to claim 1,
wherein the etching apparatus included in each of the third cluster, the sixth cluster, and the ninth cluster is a dry etching apparatus.

8. The manufacturing equipment for a light-emitting device according to claim 1,
wherein the etching apparatus included in the tenth cluster is a wet etching apparatus.

9. The manufacturing equipment for a light-emitting device according to claim 1, further comprising:
an application apparatus, a light-exposure apparatus, a developing apparatus, and a baking apparatus as the plurality of apparatuses where the lithography step is performed.

10. The manufacturing equipment for a light-emitting device according to claim 1, further comprising:
an application apparatus and a nanoimprint apparatus as the plurality of apparatuses where the lithography step is performed.

11. The manufacturing equipment for a light-emitting device according to claim 1,
wherein the substrate reversing device comprises a rotation mechanism and a stage where an electrostatic adsorption unit, an electromagnet unit, and a cylinder unit are stacked in this order,
wherein the electrostatic adsorption unit holds a substrate, and
wherein the rotation mechanism reverses the stage.

12. The manufacturing equipment for a light-emitting device according to claim 11,
wherein the cylinder unit is configured to move up and down a plurality of pusher pins, and
wherein the pusher pins are provided in through holes formed in the electrostatic adsorption unit and the electromagnet unit.

13. The manufacturing equipment for a light-emitting device according to claim 11,
wherein the face-down deposition apparatus comprises a mask jig and an alignment mechanism,
wherein the alignment mechanism is connected to a lifting mechanism, and
wherein after the stage is reversed, the mask jig is aligned to touch the substrate and then is closely attached to the substrate with the electromagnet unit.

14. The manufacturing equipment for a light-emitting device according to claim 12,
wherein the face-down deposition apparatus comprises a mask jig and an alignment mechanism,
wherein the alignment mechanism is connected to a lifting mechanism, and
wherein after the stage is reversed, the mask jig is aligned to touch the substrate and then is closely attached to the substrate with the electromagnet unit.
